(19) United States
(12) Patent Application Publication
(10) Pub. No.: US 2022/0415970 A1
(43) Pub. Date: Dec. 29, 2022

(54) IMAGE SENSOR AND IMAGING SYSTEM

(71) Applicant: Panasonic Intellectual Property Management Co., Ltd., Osaka (JP)

(72) Inventor: KATSUYA NOZAWA, Osaka (JP)

(21) Appl. No.: 17/821,816

(22) Filed: Aug. 24, 2022

Related U.S. Application Data
(63) Continuation of application No. PCT/JP2021/002186, filed on Jan. 22, 2021.

(30) Foreign Application Priority Data
Mar. 5, 2020 (JP) 2020-037773

(51) Int. Cl. H01L 27/30; H01L 51/00; G01S 17/89; H04N 5/359

(52) U.S. Cl. CPC H01L 27/307; H01L 51/0048; G01S 17/89; H04N 5/359; H01L 51/4246

(57) ABSTRACT

An image sensor includes a function layer including a photoelectric conversion region containing a plurality of semiconductor-type carbon nanotubes; a transparent electrode that collects first electric charges that are positive electric charges or negative electric charges, the positive electric charges or the negative electric charges being generated in the photoelectric conversion region upon entry of light; a first collection electrode that collects second electric charges having a polarity opposite to the first electric charges among the positive electric charges and the negative electric charges; a second collection electrode that collects the second electric charges; a first control electrode that controls movement of the second electric charges toward the first collection electrode; a second control electrode that controls movement of the second electric charges toward the second collection electrode; and an electric charge accumulator in which the second electric charges collected by the first collection electrode are accumulated.

### BACKGROUND

### 1. Technical Field

The present disclosure relates to an image sensor and an imaging system. More specifically, the present disclosure relates to an image sensor and an imaging system for sensitivity modulation imaging that can be used for imaging such as imaging of a range image and imaging of a periodic phenomenon.

### 2. Description of the Related Art

An image sensor is a device that accumulates, in electric charge accumulation parts, electric charges generated due to entry of light into photoelectric conversion regions provided for respective units called pixels and measures an amount of electric charges accumulated in each of the electric charge accumulation parts.

A range image sensor is a device that has a function of measuring, for each pixel, a distance from the range image sensor to a subject.

An indirect Time of Flight (TOF) method is known as a method for measuring a distance from a range image sensor to a subject, that is, as a distance measurement method.

According to the indirect TOF method, a light source irradiates a subject with modulated light whose intensity changes at a specific frequency. The modulated light reflected by the subject enters a range image sensor through an imaging optical system and the like. Hereinafter, modulated light for distance measurement whose intensity periodically changes is sometimes referred to simply as “modulated light”.

A range image sensor has a function of temporally changing a rate of electric charges accumulated in electric charge accumulation parts among electric charge generated in photoelectric conversion regions at a frequency identical to a change of an intensity of modulated light. Hereinafter, the rate of electric charges accumulated in the electric charge accumulation parts among electric charge generated in the photoelectric conversion regions is sometimes referred to simply as a “collection rate”.

Amounts of electric charges accumulated in the electric charge accumulation parts are determined by a relationship between a phase of a temporal change of the collection rate and a phase of an intensity of incident modulated light. The phase of a temporal change of the collection rate is set by a user and is known. It is therefore possible to determine the phase of an intensity of incident modulated light on the basis of the amounts of electric charges accumulated in the electric charge accumulation parts. The phase of an intensity of incident modulated light depends on a sum of a distance from a light source to a subject and a distance from the subject to the range image sensor, and therefore, a distance to the subject can be measured on the basis of the phase of the incident modulated light determined by the range image sensor.

Distance measurement accuracy of the range image sensor depends on a modulation frequency of the modulated light. The distance measurement accuracy becomes higher as the modulation frequency becomes higher.

Examples of the range image sensor are disclosed in Japanese Patent No. 4235729 and U.S. Patent Application Publication No. 2019/0252455.

Japanese Patent No. 4235729 discloses a range image sensor in which a photoelectric conversion region and an electric charge accumulation part are provided on the same surface of the same single-crystal silicon.

U.S. Patent Application Publication No. 2019/0252455 discloses a range image sensor in which a photoelectric conversion region and an electric charge transport layer are laminated. Furthermore, in the range image sensor disclosed in U.S. Patent Application Publication No. 2019/0252455, an electric charge accumulation region is provided in single-crystal silicon. The range image sensor disclosed in U.S. Patent Application Publication No. 2019/0252455 changes a rate of electric charges distributed to two electric charge accumulation parts by moving positive electric charges or negative electric charges generated in the photoelectric conversion region to the electric charge transport layer and modulation-controlling movement of the electric charges in the electric charge transport layer by using a modulating electrode.

Japanese Unexamined Patent Application Publication No. 2017-201695 discloses an image sensor in which carbon nanotubes are used as a photoelectric conversion material.

### SUMMARY

In one general aspect, the techniques disclosed here feature an image sensor including a function layer including a photoelectric conversion region containing a plurality of semiconductor-type carbon nanotubes; a transparent electrode that collects first electric charges that are positive electric charges or negative electric charges, the positive electric charges or the negative electric charges being generated in the photoelectric conversion region upon entry of light; a first collection electrode that collects second electric charges having a polarity opposite to the first electric charges among the positive electric charges and the negative electric charges; a second collection electrode that collects the second electric charges; a first control electrode that controls movement of the second electric charges toward the first collection electrode; a second control electrode that controls movement of the second electric charges toward the second collection electrode; and an electric charge accumulator in which the second electric charges collected by the first collection electrode are accumulated.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a circuit diagram illustrating an exemplary circuit configuration of an image sensor according to Embodiment 1;

FIG. 2 is a circuit diagram illustrating an exemplary circuit configuration of a pixel according to Embodiment 1;

FIG. 3 is a cross-sectional view schematically illustrating a device structure of the pixel according to Embodiment 1;

FIG. 4 is a schematic view illustrating a structure of a carbon nanotube;

FIG. 5 is a schematic view illustrating an example of an absorption spectrum of a semiconductor-type carbon nanotube;

FIG. 6 illustrates first resonance wavelengths and second resonance wavelengths of semiconductor-type carbon nanotubes having representative chirality;

FIG. 7 is a schematic view for explaining a length of a semiconductor-type carbon nanotube;

FIG. 8 is a schematic view for explaining a way in which the semiconductor-type carbon nanotubes are disposed in the function layer according to Embodiment 1;

FIG. 9 is a view for explaining a length of a semiconductor-type carbon nanotube in top view;

FIG. 10 is a cross-sectional view schematically illustrating a device structure of a pixel according to another example of Embodiment 1;

FIG. 11 schematically illustrates a potential distribution of the function layer in step 5A and a potential distribution of the function layer in step 5B;

FIG. 12 illustrates an example of a temporal change of an intensity of modulated light entering the image sensor according to Embodiment 1 and voltages applied to a first control electrode and a second control electrode; and

FIG. 13 is a block diagram illustrating an example of a configuration of an imaging system according to Embodiment 2.

### DETAILED DESCRIPTIONS

Among conventional range image sensors, the range image sensor described in Japanese Patent No. 4235729 is configured such that a photoelectric conversion region and an electric charge accumulation part are provided on the same surface of the same single-crystal silicon substrate. Accordingly, spectral sensitivity characteristics of the range image sensor is limited by characteristics of single-crystal silicon. Specifically, the range image sensor has low sensitivity to a wavelength longer than visible light and is hard to be configured so as to have sensitivity to wavelengths equal to or longer than 1100 nanometers. Furthermore, a thickness of the photoelectric conversion region needs to be sufficiently large in order to give high sensitivity to wavelengths equal to or longer than 850 nanometers even though the wavelengths are equal to or shorter than 1100 nanometers. In a case where the thickness of the photoelectric conversion region is large, there arises a problem that light incident from an oblique direction is not absorbed by a photoelectric conversion region of a proper pixel but enters a photoelectric conversion region of an adjacent pixel. It is therefore difficult to make pixels small. That is, there arises a need to increase the whole range image sensor or a need to limit the number of pixels to assure distance measurement accuracy. The former negatively affects a production cost of the range image sensor and design of an imaging optical system.

Although a range image sensor needs to detect modulated light, in a case where a light component other than the modulated light is included in a lighting for a subject, electric charges generated by light other than the modulated light becomes noise and decreases distance measurement accuracy. For example, sunlight has a component of a wavelength equal to or shorter than 850 nanometers, and this component is stronger than a component of a wavelength equal to or longer than 850 nanometers. Accordingly, a conventional range image sensor is strongly affected by sunlight and is hard to be used outdoor in the daytime.

Furthermore, sunlight has a wavelength region that has strongly attenuated due to influence of atmosphere within a wavelength range from approximately 1350 nanometers to 1450 nanometers. If this wavelength region can be used as modulated light, influence of sunlight can be markedly decreased even in the daytime, but it is hard to use this wavelength region in a conventional range image sensor.

Furthermore, in the conventional range image sensor, the photoelectric conversion region and the electric charge accumulation part are provided on the same surface of the same single-crystal silicon substrate so as to be located at different positions within the surface. It is therefore necessary to divide a limited surface area between the photoelectric conversion region and the electric charge accumulation part. Although the photoelectric conversion region needs to be made wide in order to improve sensitivity and the electric charge accumulation part needs to be made wide in order to increase a saturated light amount, it is difficult to achieve both an improvement in sensitivity and an increase in saturated light amount because of the above reason. Furthermore, in the conventional range image sensor, not only the photoelectric conversion region and the electric charge accumulation part, but also a transistor for controlling transfer of electric charges, a circuit for measuring an electric charge amount, and the like are provided on the same surface of the same single-crystal silicon substrate, and it is therefore difficult to make the photoelectric conversion region large.

According to the method of U.S. Patent Application Publication No. 2019/0252455, the photoelectric conversion region and the electric charge accumulation part are made of different materials and are disposed on different planes. Accordingly, the limitation of a sensitivity wavelength and limitation of a size of the photoelectric conversion region that occur in Japanese Patent No. 4235729 are weaker.

However, in the range image sensor of U.S. Patent Application Publication No. 2019/0252455, a rate of distribution of electric charges to the two electric charge accumulation parts can be changed only after electric charges move to the electric charge transport layer. The rate of distribution cannot be changed until electric charges move from the photoelectric conversion region to the electric charge transport layer. This makes it impossible to follow a change in intensity of modulated light that occurs before completion of the movement, thereby making it impossible to increase a frequency of modulation control. It is therefore hard to increase a modulation frequency of the modulated light. For example, it takes a shorter time for electric charges generated at a position in the photoelectric conversion region closer to the electric charge transport layer to move to the electric charge transport layer. However, it takes a longer time for electric charges generated at a position in the photoelectric conversion region farther from the electric charge transport layer to move to the electric charge transport layer. The photoelectric conversion region of the range image sensor disclosed in U.S. Patent Application Publication No. 2019/0252455 is made of quantum dots. The quantum dots allow electric charges to move only by hopping, and therefore mobility of electric charges in the photoelectric conversion region is low.

Therefore, according to the method of U.S. Patent Application Publication No. 2019/0252455, it is hard to increase distance measurement accuracy.

In view of the above circumstances, it is desired that an image sensor used for distance measurement can change a rate of distribution of electric charges while following even modulated light of a high modulation frequency, that is, can, for example, control movement of electric charges at a high speed and thereby improves distance measurement accuracy.

The present disclosure provides an image sensor and others that can control movement of electric charges at a high speed. Summary of Present Disclosure

An aspect of the present disclosure is summarized as follows.

An image sensor according to an aspect of the present disclosure includes a function layer including a photoelectric conversion region containing a plurality of semiconductor-type carbon nanotubes; a transparent electrode that collects first electric charges that are positive electric charges or negative electric charges, the positive electric charges or the negative electric charges being generated in the photoelectric conversion region upon entry of light; a first collection electrode that collects second electric charges having a polarity opposite to the first electric charges among the positive electric charges and the negative electric charges; a second collection electrode that collects the second electric charges; a first control electrode that controls movement of the second electric charges toward the first collection electrode; a second control electrode that controls movement of the second electric charges toward the second collection electrode; and an electric charge accumulator in which the second electric charges collected by the first collection electrode are accumulated.

According to this configuration, movement of the second electric charges toward the first collection electrode and the second collection electrode is controlled by the first control electrode and the second control electrode, and the second electric charges are distributed into and collected by the first collection electrode and the second collection electrode. Furthermore, since mobility of electric charges is high inside the semiconductor-type carbon nanotubes, mobility of the second electric charges in the photoelectric conversion region containing the plurality of semiconductor-type carbon nanotubes is high. Accordingly, in a case where the second electric charges are alternately moved to the first collection electrode and the second collection electrode, even in a case where a frequency of modulation control of controlling the movement and distributing the second electric charges is high, the second electric charges are easily moved to the first collection electrode and the second collection electrode while following the high frequency of the modulation control. Therefore, the image sensor according to this aspect can control movement of electric charges at a high speed. As a result, for example, a modulation frequency of modulated light used for distance measurement that contributes to an improvement of distance measurement accuracy can be increased, and therefore distance measurement accuracy can be improved.

Furthermore, for example, the function layer may further include: an electric charge exchange region in which the second electric charges generated in the photoelectric conversion region are exchanged with the first collection electrode; and an electric charge transport region located between the photoelectric conversion region and the electric charge exchange region; movement of the second electric charges from the photoelectric conversion region to the electric charge exchange region through the electric charge transport region may be controlled by the first control electrode; and the electric charge exchange region and the electric charge transport region may each contain the plurality of semiconductor-type carbon nanotubes.

According to this configuration, the function layer includes the photoelectric conversion region, the electric charge transport region, and the electric charge exchange region each containing the plurality of semiconductor-type carbon nanotubes, and therefore mobility of the second electric charges from the photoelectric conversion region to the electric charge exchange region can be increased.

Furthermore, for example, at least one of the plurality of semiconductor-type carbon nanotubes may extend from the photoelectric conversion region to the electric charge exchange region.

According to this configuration, the second electric charges generated in the semiconductor-type carbon nanotube extending from the photoelectric conversion region to the electric charge exchange region can move to the electric charge exchange region just by passing through the semiconductor-type carbon nanotube. It is therefore possible to increase mobility of the second electric charges.

Furthermore, for example, a thickness of the function layer may be smaller than a distance between the electric charge exchange region and the photoelectric conversion region.

According to this configuration, the thickness of the function layer is smaller than a distance over which the second electric charges are moved from the photoelectric conversion region to the electric charge exchange region, and therefore the plurality of semiconductor-type carbon nanotubes are easily located close to the first control electrode. This makes it easy to control movement of the second electric charges in the electric charge transport region, thereby increasing efficiency of collection of the second electric charges by the first collection electrode.

Furthermore, for example, an average length of the plurality of semiconductor-type carbon nanotubes may be larger than a thickness of the function layer.

According to this configuration, the average length of the plurality of semiconductor-type carbon nanotubes is larger than the thickness of the function layer, and therefore axes of the cylinders of the plurality of semiconductor-type carbon nanotubes are more likely to be oriented in a direction perpendicular to a thickness direction of the function layer. That is, the axes of the cylinders of the plurality of semiconductor-type carbon nanotubes are more likely to be oriented in a direction extending from the photoelectric conversion region toward the electric charge exchange region through the electric charge transport region. As a result, mobility of the second electric charges in a direction from the photoelectric conversion region toward the electric charge exchange region through the electric charge transport region can be increased.

Furthermore, for example, the transparent electrode may be located above the function layer; the first collection electrode and the second collection electrode may be located below the function layer and face the transparent electrode; the first control electrode and the second control electrode may be located below the function layer, the first control electrode and the second control electrode facing the transparent electrode, the first control electrode and the second control electrode being located between the first collection electrode and the second collection electrode; the electric charge exchange region may be located between the first collection electrode and the transparent electrode; and the electric charge transport region may be located between the first control electrode and the transparent electrode, the electric charge transport region being adjacent to the photoelectric conversion region and the electric charge exchange region.

According to this configuration, the photoelectric conversion region, the electric charge transport region, and the electric charge exchange region are arranged adjacent to one another in the function layer, and therefore mobility of the second electric charges from the photoelectric conversion region to the electric charge exchange region can be increased.

Furthermore, for example, the image sensor may further include a bias electrode that is located below the function layer and that faces the transparent electrode with the photoelectric conversion region interposed between the transparent electrode and the bias electrode.

According to this configuration, a voltage difference can be given between the transparent electrode and the bias electrode, and therefore an electric field can be generated in the photoelectric conversion region. As a result, the positive electric charges and the negative electric charges generated in the photoelectric conversion region are easily separated, and disappearance of electric charges caused by reunion can be suppressed. It is therefore possible to increase an amount of second electric charges collected by the electric charge accumulation part and increase sensitivity even by brief exposure to light. As a result, for example, accurate distance measurement can be performed.

Furthermore, for example, the image sensor may further include a lens that is located above the transparent electrode and that focuses light coming from an upper side onto the photoelectric conversion region; and a light-shielding body located between the transparent electrode and the lens. The light-shielding body may be located outside the photoelectric conversion region and may overlap the electric charge exchange region and the electric charge transport region in top view.

According to this configuration, an amount of light entering the photoelectric conversion region can be increased and photoelectric conversion efficiency can be increased, and occurrence of electric charges in a portion other than the photoelectric conversion region of the function layer can be suppressed. It is therefore possible to suppress noise caused by electric charges generated in a portion other than the photoelectric conversion region while increasing photoelectric conversion efficiency. As a result, for example, it is possible to increase distance measurement accuracy.

Furthermore, for example, the photoelectric conversion region may further contain an acceptor material that receives the first electric charges generated in the photoelectric conversion region.

According to this configuration, the first electric charges generated in the plurality of semiconductor-type carbon nanotubes are extracted by the acceptor material, and therefore disappearance of electric charges caused by reunion of the first electric charges and the second electric charges is suppressed. Furthermore, the second electric charges remain in the plurality of semiconductor-type carbon nanotubes that allows movement of high mobility, and can move inside the plurality of semiconductor-type carbon nanotubes.

An imaging system according to an aspect of the present disclosure includes the image sensor; and a light source that emits light of a wavelength including a resonance wavelength of the plurality of semiconductor-type carbon nanotubes.

According to this configuration, the image sensor is provided, and a wavelength to which the image sensor has high sensitivity is emitted from the light source, and therefore the imaging system according to this aspect can control movement of electric charges at a high speed and increase sensitivity. As a result, for example, an imaging system having high sensitivity and high accuracy in distance measurement accuracy can be achieved.

Embodiments of the present disclosure are described below with reference to the drawings.

Note that the embodiments below each illustrate a general or specific example. Numerical values, shapes, materials, constituent elements, positions of the constituent elements, a way in which the constituent elements are connected, steps, an order of steps, and the like illustrated in the embodiments below are merely examples and do not limit the present disclosure.

Furthermore, in the present specification, description of elements that are essential for operation of an image sensor or effective for improvement of characteristics but are unnecessary for description of the present disclosure is omitted. Furthermore, the drawings merely illustrate concepts and do not take a scale, a shape, and the like into consideration at all. Accordingly, for examples, the drawings do not necessarily match each other in scale and the like. Furthermore, substantially identical elements are given identical reference signs, and repeated description thereof is omitted or simplified.

In the present specification, terms such as “equal” indicating a relationship between elements, terms such as “square” and “circular” indicating a shape of an element, and numerical ranges are not necessarily strict expressions but expressions encompassing substantially equivalent ranges, for example, differences of approximately several percent.

In the present specification, terms such as “upper” and “lower” does not refer to an upper side (e.g., a vertically upper side) and a lower side (e.g., a vertically lower side) in absolute spatial recognition but are used as terms defined depending on a relative positional relationship based on a laminating order in a laminated configuration. Specifically, a light-receiving side of an image sensor is referred to as an “upper” side, and a side opposite to the light-receiving side is referred to as a “lower” side. Similarly, a surface of each member that faces the light-receiving side of the image sensor is referred to as an “upper surface”, and a surface of each member that faces the side opposite to the light-receiving side of the image sensor is referred to as a “lower surface”. Note that terms such as “upper side”, “lower side”, “upper surface”, and “lower surface” are merely used to designate relative positions of members and do not intend to limit a posture of the image sensor during use. Furthermore, the terms “upper side” and “lower side” are applied not only in a case where two constituent elements are disposed apart from each other and another constituent element is present between the two constituent elements, but also in a case where two constituent elements are disposed in close contact with each other. The “top view” refers to a case where a semiconductor substrate is viewed from above along a direction perpendicular to a main surface of the semiconductor substrate.

### Embodiment 1

An image sensor according to Embodiment 1 is described below.

### [1. Circuit Configuration of Image Sensor]

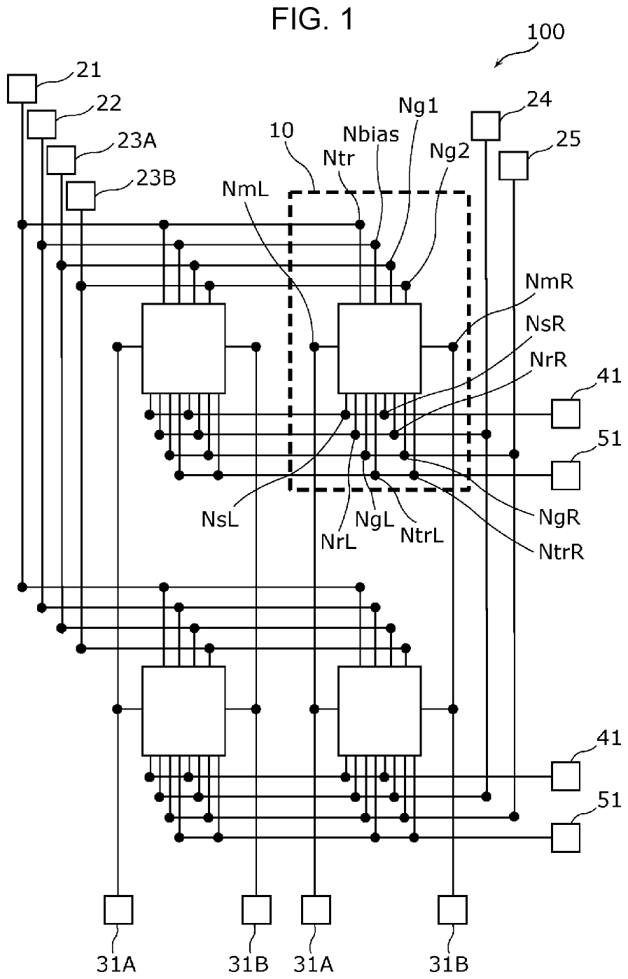

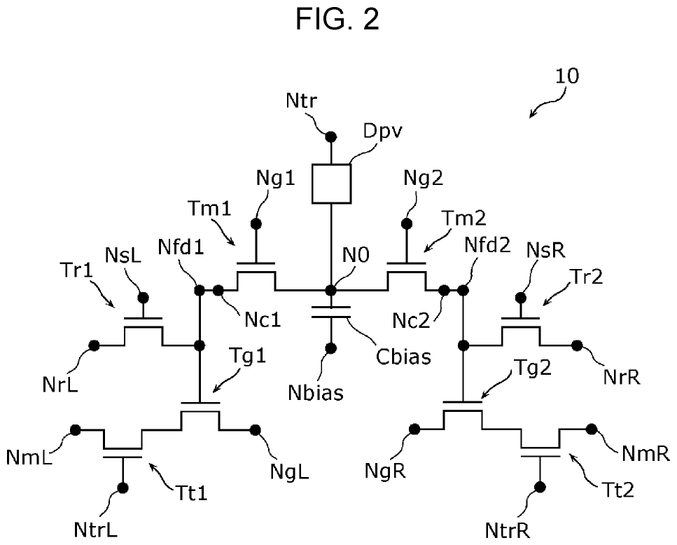

First, a circuit configuration of an image sensor according to the present embodiment is described with reference to FIGS. 1 and 2.

FIG. 1 is a circuit diagram illustrating an exemplary circuit configuration of an image sensor 100 according to the present embodiment. As illustrated in FIG. 1, the image sensor 100 includes a plurality of pixels 10 arranged two-dimensionally. FIG. 1 is a circuit diagram illustrating a case where four pixels 10 arranged in two rows and two columns are integrated. The number of pixels 10 and a way in which the pixels 10 are arranged in the image sensor 100 are not limited to the example illustrated in FIG. 1. For example, the image sensor 100 may be a line sensor in which a plurality of pixels 10 are arranged in one line. Furthermore, the number of pixels 10 included in the image sensor 100 may be one.

The image sensor 100 includes, as a peripheral circuit including a control unit that controls operation of the pixels 10, a voltage control unit 21, a voltage control unit 22, a control mechanism 23A, a control mechanism 23B, an electric charge accumulation region reset mechanism 24, a voltage control unit 25, an electric charge amount measuring device 31A, an electric charge amount measuring device 31B, a control mechanism 41, and a control mechanism 51.

Each of the pixels 10 has a terminal Ntr, a terminal Nbias, a terminal Ng1, a terminal Ng2, a terminal NmL, a terminal NmR, a terminal NsL, a terminal NsR, a terminal NrL, a terminal NrR, a terminal NgL, a terminal NgR, a terminal NtrL, and a terminal NtrR. Details of a circuit configuration of each of the pixels 10 will be described later.

The terminal Ntr of each of the pixels 10 is connected to the voltage control unit 21. The voltage control unit 21 has a function of setting a voltage of the terminal Ntr to a preset voltage V_tr. Specifically, the voltage control unit 21 may include a constant-voltage power supply, a variable-voltage power supply, and a grounding wire.

The terminal Nbias of each of the pixels 10 is connected to the voltage control unit 22. The voltage control unit 22 has a function of setting a voltage of the terminal Nbias to a preset voltage V_bias. Specifically, the voltage control unit 22 may include a constant-voltage power supply, a variable-voltage power supply, and a grounding wire.

The terminal Ng1 of each of the pixels 10 is connected to a control mechanism 23A. The control mechanism 23A has a function of controlling opening and closing of a first modulation transistor Tm1, which will be described later, at a designated frequency and in a designated phase. Specifically, the control mechanism 23A may be a device including a circuit that generates a signal whose frequency, phase, and voltage have been controlled. The control mechanism 23A may be configured as a circuit provided in the image sensor or may be configured by using an external function generator or the like.

The terminal Ng2 of each of the pixels 10 is connected to the control mechanism 23B. The control mechanism 23B has a function of controlling opening and closing of a second modulation transistor Tm2, which will be described later, at a designated frequency and in a designated phase. Specifically, the control mechanism 23B may be configured as a device including a circuit that generates a signal whose frequency, phase, and voltage have been controlled. The control mechanism 23B may be configured as a circuit provided in the image sensor or may be configured by using an external function generator or the like.

The control mechanism 23A and the control mechanism 23B may be different mechanisms. Alternatively, the control mechanism 23A and the control mechanism 23B may share a signal generator such as a function generator and be provided with a delay line or the like so that phases thereof differ from each other.

The terminal NmL of each of the pixels 10 constituting each column is connected to the electric charge amount measuring device 31A. A plurality of electric charge amount measuring devices 31A are provided corresponding to the columns of the pixels 10. Each of the electric charge amount measuring devices 31A has a function of measuring an amount of signal electric charges accumulated in a first electric charge accumulation region Nfd1 (described later) of each of the pixels 10 constituting a corresponding column. Specifically, each of the electric charge amount measuring devices 31A may be an AD converter or the like constituted by members such as a transistor. In the present embodiment, the pixels 10 constituting each column share a single electric charge amount measuring device 31A, and measurement is performed by switching connection. Note that independent electric charge amount measuring devices 31A may be provided for the respective pixels 10 constituting each column.

The terminal NmR of each of the pixels 10 constituting each column is connected to the electric charge amount measuring device 31B. A plurality of electric charge amount measuring devices 31B are provided corresponding to the columns of the pixels 10. Each of the electric charge amount measuring devices 31B has a function of measuring an amount of signal electric charges accumulated in a second electric charge accumulation region Nfd2 (described later) of each of the pixels 10 constituting a corresponding column. Specifically, each of the electric charge amount measuring devices 31B may be an AD converter or the like constituted by members such as a transistor. In the present embodiment, the pixels 10 constituting each column share a single electric charge amount measuring device 31B, and measurement is performed by switching connection. Note that independent electric charge amount measuring devices 31B may be provided for the respective pixels 10 constituting each column. It is also possible to employ a configuration in which the electric charge amount measuring device 31A and the electric charge amount measuring device 31B are the same circuit and connection is switched as needed. Furthermore, signal electric charge amounts measured by the electric charge amount measuring devices 31A and the electric charge amount measuring devices 31B are read out by a readout circuit or the like (not illustrated).

The terminal NsL and the terminal NsR of each of the pixels 10 constituting each row are connected to the control mechanism 41. A plurality of control mechanisms 41 are provided corresponding to the rows of the pixels 10. Each of the control mechanisms 41 has a function of controlling opening and closing of a first reset transistor Tr1 (described later) connected to the first electric charge accumulation region Nfd1 of each of the pixels 10 constituting a corresponding row and opening and closing of a second reset transistor Tr2 (described later) connected to the second electric charge accumulation region Nfd2 of each of the pixels 10 constituting the corresponding row. Specifically, the control mechanism 41 may be configured as a circuit that sets a voltage to a predetermined value at a predetermined timing.

The terminal NrL and the terminal NrR of each of the pixels 10 are connected to the electric charge accumulation region reset mechanism 24. The electric charge accumulation region reset mechanism 24 has a function of removing signal electric charges accumulated in the first electric charge accumulation region Nfd1 and the second electric charge accumulation region Nfd2, that is, resetting a voltage of the first electric charge accumulation region Nfd1 and a voltage of the second electric charge accumulation region Nfd2 to a reset voltage. Specifically, the electric charge accumulation region reset mechanism 24 may include a constant-voltage power supply, a variable-voltage power supply, and a grounding wire.

The terminal NtrL and the terminal NtrR of each of the pixels 10 constituting each row are connected to the control mechanism 51. A plurality of control mechanisms 51 are provided corresponding to the rows of the pixels 10. Each of the control mechanisms 51 has a function of performing control so that electric charges accumulated in the first electric charge accumulation region Nfd1 of the pixel 10 in a designated row at a designated time are transferred to the electric charge amount measuring device 31A and electric charges accumulated in the second electric charge accumulation region Nfd2 of the pixel 10 in a designated row at a designated time are transferred to the electric charge amount measuring device 31B. Specifically, the control mechanism 51 may be configured as a circuit that sets a voltage to a predetermined value at a predetermined timing.

The terminal NgL and the terminal NgR of each of the pixels 10 are connected to the voltage control unit 25. The voltage control unit 25 has a function of setting the terminal NgL and the terminal NgR of each of the pixels 10 to a predetermined voltage. Specifically, the voltage control unit 25 may include a constant-voltage power supply and a grounding wire.

Next, a circuit configuration of each of the pixels 10 is described. FIG. 2 is a circuit diagram illustrating an exemplary circuit configuration of each of the pixels 10.

As illustrated in FIG. 2, each of the pixels 10 of the image sensor 100 has a photoelectric conversion element Dpv, the first modulation transistor Tm1, the second modulation transistor Tm2, the first reset transistor Trl, the second reset transistor Tr2, a first amplifier transistor Tg1, a second amplifier transistor Tg2, a first transfer transistor Tt1, a second transfer transistor Tt2, the first electric charge accumulation region Nfd1, the second electric charge accumulation region Nfd2, a terminal Nc1, a terminal Nc2, and a bias application capacitor Cbias.

The photoelectric conversion element Dpv has a function of generating positive electric charges and negative electric charges upon irradiation of light. The photoelectric conversion element Dpv is connected to the terminal Ntr and a region N0. The positive electric charges and the negative electric charges generated in the photoelectric conversion element Dpv move to different terminals due to a difference in potential between the terminal Ntr and the region N0. For example, in a case where the voltage V_tr of the terminal Ntr is higher than a voltage V_0 of the region N0, the negative electric charges move to the terminal Ntr side, and the positive electric charges move to the region N0 side. In a case where the voltage V_tr of the terminal Ntr is lower than the voltage V_0 of the region N0, the positive electric charges move to the terminal Ntr side, and the negative electric charges move to the region N0 side.

The region N0 is connected to a source of the first modulation transistor Tm1 and a source of the second modulation transistor Tm2.

The first modulation transistor Tm1 is a field-effect transistor. Conduction and cut-off states between the source and a drain of the first modulation transistor Tm1 is switched by control of a gate voltage of the first modulation transistor Tm1. Hereinafter, conduction and cut-off are sometimes referred simply as “opening and closing”.

A gate of the first modulation transistor Tm1 is connected to the terminal Ng1. The source of the first modulation transistor Tm1 is connected to the region N0. The drain of the first modulation transistor Tm1 is connected to the first electric charge accumulation region Nfd1 with the terminal Nc1 interposed therebetween.

The terminal Nc1 is connected to the drain of the first modulation transistor Tm1 and the first electric charge accumulation region Nfd1. That is, the terminal Nc1 relays connection between the drain of the first modulation transistor Tm1 and the first electric charge accumulation region Nfd1.

The first electric charge accumulation region Nfd1 is a region in which some of electric charges generated in the photoelectric conversion element Dpv and moved to the region N0 are accumulated.

As described above, the terminal Ng1 is connected to the control mechanism 23A.

The second modulation transistor Tm2 is a field-effect transistor. Opening and closing states between the source and a drain of the second modulation transistor Tm2 are switched by control of a gate voltage of the second modulation transistor Tm2.

A gate of the second modulation transistor Tm2 is connected to the terminal Ng2. The source of the second modulation transistor Tm2 is connected to the region N0. The drain of the second modulation transistor Tm2 is connected to the second electric charge accumulation region Nfd2 with the terminal Nc2 interposed therebetween.

The second electric charge accumulation region Nfd2 is a region where some of electric charges generated in the photoelectric conversion element Dpv and moved to the region N0 side are accumulated.

The terminal Nc2 is connected to the drain of the second modulation transistor Tm2 and the second electric charge accumulation region Nfd2. That is, the terminal Nc2 relays connection between the drain of the second modulation transistor Tm2 and the second electric charge accumulation region Nfd2.

As described above, the terminal Ng2 is connected to the control mechanism 23B.

The first reset transistor Tr1 and the second reset transistor Tr2 are field-effect transistors. Opening and closing states between a source and a drain of the first reset transistor Tr1 and between a source and a drain of the second reset transistor Tr2 are switched by control of a gate voltage of the first reset transistor Tr1 and a gate voltage of the second reset transistor Tr2.

A gate of the first reset transistor Tr1 is connected to the terminal NsL. The source of the first reset transistor Tr1 is connected to the terminal NrL. The drain of the first reset transistor Tr1 is connected to the first electric charge accumulation region Nfd1.

A gate of the second reset transistor Tr2 is connected to the terminal NsR. The source of the second reset transistor Tr2 is connected to the terminal NrR. The drain of the second reset transistor Tr2 is connected to the second electric charge accumulation region Nfd2.

The first amplifier transistor Tg1 and the second amplifier transistor Tg2 are field-effect transistors. Values of drain electric current of the first amplifier transistor Tg1 and the second amplifier transistor Tg2 change depending on values of the gate voltages of the first amplifier transistor Tg1 and the second amplifier transistor Tg2.

A gate of the first amplifier transistor Tg1 is connected to the first electric charge accumulation region Nfd1. A source of the first amplifier transistor Tg1 is connected to the terminal NgL. A drain of the first amplifier transistor Tg1 is connected to the source of the first transfer transistor Tt1.

A gate of the second amplifier transistor Tg2 is connected to the second electric charge accumulation region Nfd2. A source of the second amplifier transistor Tg2 is connected to the terminal NgR. A drain of the second amplifier transistor Tg2 is connected to the source of the second transfer transistor Tt2.

The first transfer transistor Tt1 and the second transfer transistor Tt2 are field-effect transistors. Opening and closing states between a source and a drain of the first transfer transistor Tt1 and between a source and a drain of the second transfer transistor Tt2 are switched by control of a gate voltage of the first transfer transistor Tt1 and a gate voltage of the second transfer transistor Tt2.

A gate of the first transfer transistor Tt1 is connected to the terminal NtrL. The source of the first transfer transistor Tt1 is connected to the drain of the first amplifier transistor Tg1. The drain of the first transfer transistor Tt1 is connected to the terminal NmL.

A gate of the second transfer transistor Tt2 is connected to the terminal NtrR. The source of the second transfer transistor Tt2 is connected to the drain of the second amplifier transistor Tg2. The drain of the second transfer transistor Tt2 is connected to the terminal NmR.

The bias application capacitor Cbias has a function of controlling a voltage of the region N0 by using a voltage applied to the terminal Nbias without a direct current component.

One terminal of the bias application capacitor Cbias is connected to the region N0, and the other terminal is connected to the terminal Nbias.

Note that the above circuit configuration is an example, and a circuit configuration different from the above circuit configuration may be employed. For example, the first electric charge accumulation region Nfd1 or the second electric charge accumulation region Nfd2 may be connected to only the drain of one of the first modulation transistor Tm1 and the second modulation transistor Tm2, and the drain of the other one of the first modulation transistor Tm1 and the second modulation transistor Tm2 may be connected to an electric charge discarding region such as a grounding wire.

Furthermore, three or more modulation transistors including a modulation transistor different from the first modulation transistor Tm1 and the second modulation transistor Tm2 and the subsequent pairs of circuits may be connected to the single photoelectric conversion element Dpv.

### 2. Structure of Pixel

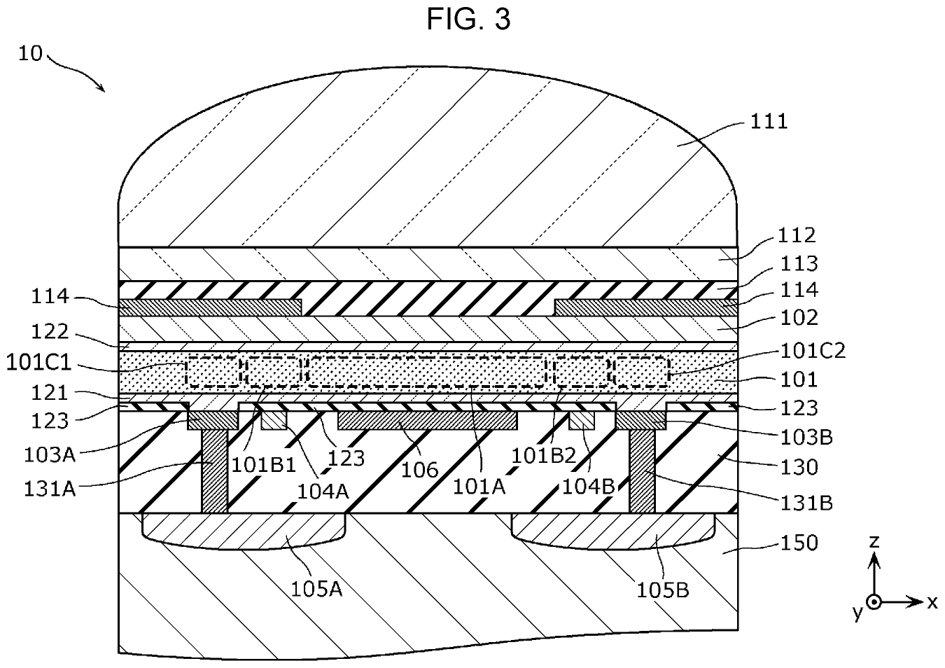

Next, a pixel structure of the image sensor 100 according to the present embodiment is described. FIG. 3 is a cross-sectional view schematically illustrating a device structure of each of the pixels 10 of the image sensor 100 according to the present embodiment. Specifically, FIG. 3 is a structure concept diagram of each of the pixels 10 of the image sensor having the above circuit function.

As illustrated in FIG. 3, each of the pixels 10 of the image sensor 100 has a function layer 101, a transparent electrode 102, a first collection electrode 103A, a second collection electrode 103B, a first control electrode 104A, a second control electrode 104B, a first electric charge accumulation region 105A, a second electric charge accumulation region 105B, an interlayer insulating layer 130, and a semiconductor substrate 150. In the present specification, the first electric charge accumulation region 105A is an example of an electric charge accumulation part.

### 2-1. Function Layer

The function layer 101 is disposed above the semiconductor substrate 150. The interlayer insulating layer 130 made of an insulating material such as silicon dioxide is disposed between the function layer 101 and the semiconductor substrate 150. Furthermore, the function layer 101 is located between the transparent electrode 102 and the first collection electrode 103A, the second collection electrode 103B, the first control electrode 104A, the second control electrode 104B, and a bias electrode 106, which will be described later. The function layer 101 may be provided so as to straddle the plurality of pixels 10 or function layers 101 may be separately provided for the respective pixels 10.

The function layer 101 includes an electric charge generating part 101A, a first transport modulation part 101B1, a second transport modulation part 101B2, a first electric charge exchange part 101C1, and a second electric charge exchange part 101C2. In the present specification, the electric charge generating part 101A is an example of a photoelectric conversion region. The first transport modulation part 101B1 is an example of an electric charge transport region, and the first electric charge exchange part 101C1 is an example of an electric charge exchange region.

The electric charge generating part 101A is a region that absorbs light and generates electric charges in the function layer 101. Specifically, the electric charge generating part 101A generates hole-electron pairs, that is, positive electric charges and negative electric charges upon entry of light. For example, the negative electric charges of one polarity are collected by the transparent electrode 102, and the positive electric charges of a polarity opposite to the negative electric charges are collected by the first collection electrode 103A and the second collection electrode 103B. In the present specification, electric charges collected by the transparent electrode 102 are referred to as first electric charges, and electric charges collected by the first collection electrode 103A and the second collection electrode 103B are referred to as second electric charges. In the above case, the first electric charges are the negative electric charges, and the second electric charges are the positive electric charges. Note that the positive electric charges may be collected by the transparent electrode 102, and the negative electric charges may be collected by the first collection electrode 103A and the second collection electrode 103B. In this case, the first electric charges are the positive electric charges, and the second electric charges are the negative electric charges.

The electric charge generating part 101A is located between the transparent electrode 102 and the bias electrode 106. Furthermore, the electric charge generating part 101A is located in a region that does not overlap a light-shielding body 114, which will be described later, in top view. Furthermore, the electric charge generating part 101A is located between the first transport modulation part 101B1 and the second transport modulation part 101B2. Furthermore, the electric charge generating part 101A is located on a plane on which the first transport modulation part 101B1, the second transport modulation part 101B2, the first electric charge exchange part 101C1, and the second electric charge exchange part 101C2 are located, and the electric charge generating part 101A, the first transport modulation part 101B1, the second transport modulation part 101B2, the first electric charge exchange part 101C1, and the second electric charge exchange part 101C2 are arranged along a direction (an x-axis direction in the example illustrated in FIG. 3) perpendicular to a thickness direction (a z-axis direction in the example illustrated in FIG. 3) of the function layer 101. The thickness direction of the function layer 101 is a direction normal to a main surface of the function layer 101.

The first transport modulation part 101B1 is a region in the function layer 101 where movement of the second electric charges generated in the electric charge generating part 101A from the electric charge generating part 101A to the first electric charge exchange part 101C1 is controlled by the first control electrode 104A.

The first transport modulation part 101B1 is located between the first control electrode 104A and the transparent electrode 102. Furthermore, the first transport modulation part 101B1 overlaps the light-shielding body 114 in top view. Furthermore, the first transport modulation part 101B1 is located between the electric charge generating part 101A and the first electric charge exchange part 101C1. The first transport modulation part 101B1 is adjacent to the electric charge generating part 101A and the first electric charge exchange part 101C1.

The second transport modulation part 101B2 is a region in the function layer 101 where movement of the second electric charges generated in the electric charge generating part 101A from the electric charge generating part 101A to the second electric charge exchange part 101C2 is controlled by the second control electrode 104B.

The second transport modulation part 101B2 is located between the second control electrode 104B and the transparent electrode 102. Furthermore, the second transport modulation part 101B2 overlaps the light-shielding body 114 in top view. Furthermore, the second transport modulation part 101B2 is located between the electric charge generating part 101A and the second electric charge exchange part 101C2. The second transport modulation part 101B2 is adjacent to the electric charge generating part 101A and the second electric charge exchange part 101C2.

The first transport modulation part 101B1 and the second transport modulation part 101B2 are in a symmetrical positional relationship with respect to the electric charge generating part 101A.

The first electric charge exchange part 101C1 is a region in the function layer 101 where the second electric charges generated in the electric charge generating part 101A are exchanged with the first collection electrode 103A.

The first electric charge exchange part 101C1 is located between the first collection electrode 103A and the transparent electrode 102. Furthermore, the first electric charge exchange part 101C1 overlaps the light-shielding body 114 in top view. Furthermore, the first electric charge exchange part 101C1 is located beside the first transport modulation part 101B1 on a side opposite to the electric charge generating part 101A.

The second electric charge exchange part 101C2 is a region in the function layer 101 where the second electric charges generated in the electric charge generating part 101A are exchanged with the second collection electrode 103B.

The second electric charge exchange part 101C2 is located between the second collection electrode 103B and the transparent electrode 102. Furthermore, the second electric charge exchange part 101C2 overlaps the light-shielding body 114 in top view. Furthermore, the second electric charge exchange part 101C2 is located beside the second transport modulation part 101B2 on a side opposite to the electric charge generating part 101A.

Furthermore, the first electric charge exchange part 101C1 and the second electric charge exchange part 101C2 are in a symmetrical positional relationship with respect to the electric charge generating part 101A.

The electric charge generating part 101A, the first transport modulation part 101B1, the second transport modulation part 101B2, the first electric charge exchange part 101C1, and the second electric charge exchange part 101C2 of the function layer 101 all contain a plurality of semiconductor-type carbon nanotubes. The plurality of semiconductor-type carbon nanotubes, for example, have absorption in a wavelength of modulated light used for distance measurement imaging. The function layer 101 may contain another material such as an acceptor material for receiving positive electric charges or negative electric charges generated in the electric charge generating part 101A, specifically, generated in the plurality of semiconductor-type carbon nanotubes. The function layer 101 is, for example, formed by applying the materials described above and other materials.

The electric charge generating part 101A, the first transport modulation part 101B1, the second transport modulation part 101B2, the first electric charge exchange part 101C1, and the second electric charge exchange part 101C2 of the function layer 101 may all have the same material composition or the same material distribution. Alternatively, the electric charge generating part 101A, the first transport modulation part 101B1, the second transport modulation part 101B2, the first electric charge exchange part 101C1, and the second electric charge exchange part 101C2 of the function layer 101 may all have different material compositions or different material distributions.

The electric charge generating part 101A corresponds to the photoelectric conversion element Dpv, the region N0, a source region of the first modulation transistor Tm1, and a source region of the second modulation transistor Tm2 in FIG. 2.

The first transport modulation part 101B1 corresponds to a channel region of the first modulation transistor Tm1.

The second transport modulation part 101B2 corresponds to a channel region of the second modulation transistor Tm2.

The first electric charge exchange part 101C1 corresponds to a drain region of the first modulation transistor Tm1.

The second electric charge exchange part 101C2 corresponds to a drain region of the second modulation transistor Tm2.

The function layer 101 may include other constituent elements. For example, in a case where the function layer 101 is provided so as to straddle the plurality of pixels 10, the function layer 101 may have a pixel separating part so that electric charges generated in each of the pixels 10 do not reach the first collection electrodes 103A and the second collection electrodes 103B of the other pixels 10. The pixel separating part need not be provided in a case where the function layers 101 are separately provided for the respective pixels 10.

### 2-1-1. Material of Function Layer

Materials such as the plurality of semiconductor-type carbon nanotubes and the acceptor material contained in the function layer 101 are described below.

First, the plurality of semiconductor-type carbon nanotubes are described.

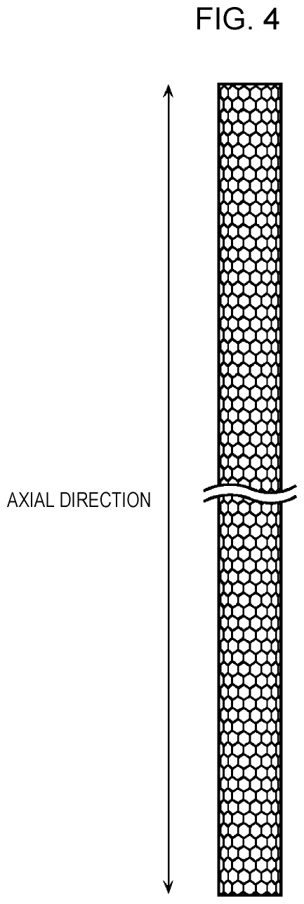

FIG. 4 is a schematic view illustrating a structure of a carbon nanotube. As illustrated in FIG. 4, a carbon nanotube is a graphene sheet made of a hexagonal lattice of carbon rolled up in a cylindrical shape.

Carbon nanotubes are classified into single-walled carbon nanotubes made of a single graphene sheet and multi-walled carbon nanotubes made of a plurality of graphene sheets. In the present embodiment, for example, single-walled carbon nanotubes are used as the carbon nanotubes from the perspective of suitability for modulation imaging. In the present specification, “carbon nanotubes” refer to single-walled carbon nanotubes unless otherwise specified.

The carbon nanotubes have two degrees of freedom, that is, chirality and a length. The chirality is an index designating which hexagonal lattice is superimposed when a graphene sheet is formed into a cylindrical shape and is defined by a pair of two integers (n, m).

Physical properties of the carbon nanotubes markedly depend on the chirality. The carbon nanotubes are metal-type carbon nanotubes in a case where 2n+m is a multiple number of 3 and are semiconductor-type carbon nanotubes in other cases.

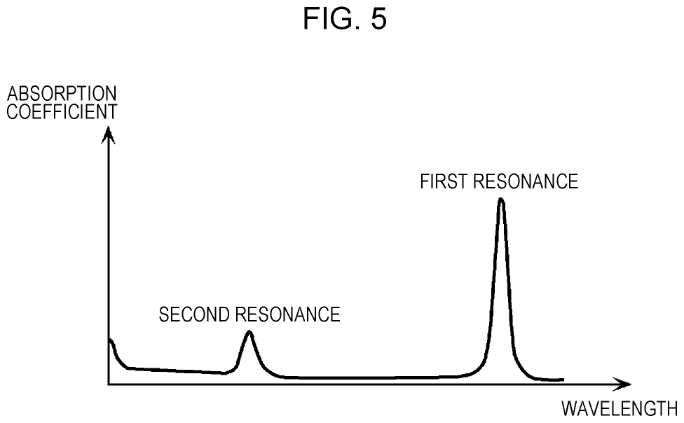

FIG. 5 is a schematic view illustrating an example of an absorption spectrum of the semiconductor-type carbon nanotubes. As illustrated in FIG. 5, the semiconductor-type carbon nanotubes exhibit a characteristic spectrum having specifically high absorption at some wavelengths. A wavelength having specifically high absorption is called a resonance wavelength. The semiconductor-type carbon nanotubes exhibit characteristics that are not observed in other molecules, that is, exhibit specifically high absorption at resonance wavelengths and low absorption at other wavelengths.

The characteristics are suitable as a photoelectric conversion material of an image sensor such as a range image sensor in which electric charges are distributed to and accumulated in a plurality of electric charge accumulation parts. For example, modulated light used for distance measurement imaging is typically limited to a specific wavelength range. When photoelectric conversion is caused by light other than modulated light, the photoelectric conversion becomes noise for distance measurement imaging and decreases distance measurement accuracy. In view of this, a range image sensor having higher sensitivity to a wavelength of modulated light and lower sensitivity to other wavelengths is more preferable.

In a case where semiconductor-type carbon nanotubes having a resonance wavelength at a wavelength of modulated light or at a wavelength close to the wavelength of the modulated light is used as a photoelectric conversion material, high sensitivity can be realized at the wavelength of the modulated light, and low sensitivity can be realized at other wavelengths. Furthermore, even in uses other than distance measurement imaging, noise can be reduced in a case where light of a specific wavelength range is received.

The resonance wavelengths of the semiconductor-type carbon nanotubes markedly differ depending on the chirality. Of the resonance wavelengths of the semiconductor-type carbon nanotubes having certain chirality, a longest resonance wavelength is referred to as a first resonance wavelength, and a second longest resonance wavelength is referred to as a second resonance wavelength.

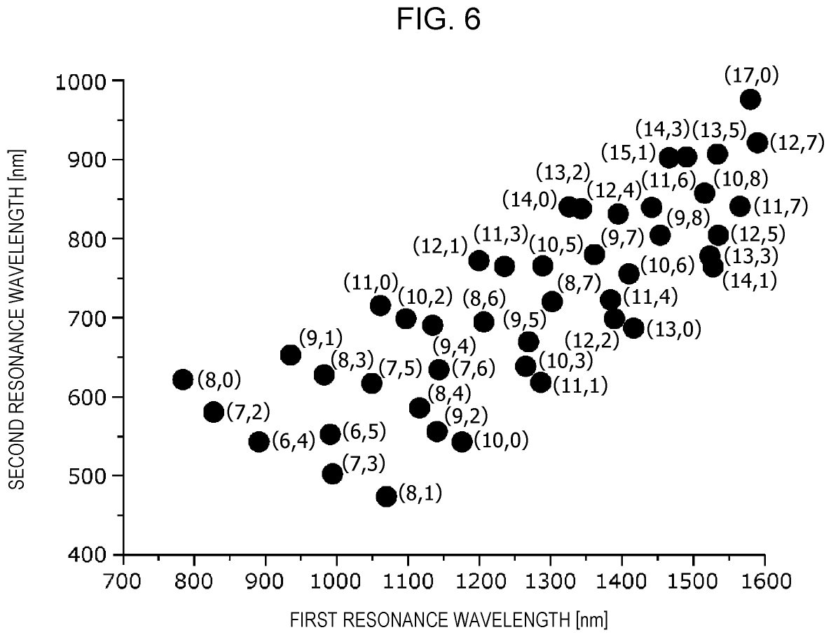

FIG. 6 illustrates first resonance wavelengths and second resonance wavelengths of semiconductor-type carbon nanotubes of representative chirality. In FIG. 6, the horizontal axis represents the first resonance wavelength, and the vertical axis represents the second resonance wavelength. Numerical values beside each plot in FIG. 6 are chirality of a semiconductor-type carbon nanotube of the plot. Although resonance wavelengths of a semiconductor-type carbon nanotube are largely decided by chirality, the resonance wavelengths change by approximately several tens of nanometers depending on a state where the semiconductor-type carbon nanotube is placed, especially due to influence of surrounding molecules and the like. In a case where a semiconductor-type carbon nanotube of chirality having a resonance wavelength at a specific wavelength needs to be selected, such a semiconductor-type carbon nanotube may be selected after checking this change of the resonance wavelength.

A semiconductor-type carbon nanotube can generate positive electric charges and negative electric charges therein by absorption of light. The positive electric charges and the negative electric charges generated in the semiconductor-type carbon nanotube can be taken out independently. Accordingly, the semiconductor-type carbon nanotube can be used as a photoelectric conversion material for exhibiting a function of a photoelectric conversion element.

According to a typical carbon nanotube synthesizing method, metal-type carbon nanotubes are synthesized together with semiconductor-type carbon nanotubes, and a proportion of the metal-type carbon nanotubes with respect to all carbon nanotubes is several tens of percent. A metal-type carbon nanotube has a function of absorbing light, but positive electric charges and negative electric charges generated in the metal-type carbon nanotube are promptly reunited and disappear. Furthermore, a metal-type carbon nanotube also has a function of causing positive electric charges and negative electric charges generated by a semiconductor-type carbon nanotube close to the metal-type carbon nanotube by absorption of light to be reunited and disappear. In view of this, a method of lowering a proportion of metal-type carbon nanotubes to the plurality of semiconductor-type carbon nanotubes included in the function layer 101 may be used in production of the function layer 101. In the function layer 101, a proportion of metal-type carbon nanotubes with respect to all carbon nanotubes may be 10% by weight or less or may be 1% by weight or less.

As a method for decreasing a proportion of metal-type carbon nanotubes after synthesizing carbon nanotubes, a method such as a gel filtration technique, an electrophoresis method, an ATPE method, a density gradient centrifugation method, or a selective polymer wrapping method can be used.

Furthermore, a sensitivity spectrum of the image sensor 100, that is, a wavelength having sensitivity depends on chirality and a proportion of the plurality of semiconductor-type carbon nanotubes included in the function layer 101. Accordingly, for example, semiconductor-type carbon nanotubes including a high proportion of semiconductor-type carbon nanotubes of chirality having a resonance wavelength at a wavelength of modulated light for distance measurement imaging or at a wavelength close to this wavelength are used as the plurality of semiconductor-type carbon nanotubes included in the function layer 101. For example, among the plurality of semiconductor-type carbon nanotubes included in the function layer 101, a proportion of semiconductor-type carbon nanotubes of chirality having a resonance wavelength at a wavelength of modulated light for distance measurement imaging or at a wavelength close to this wavelength may be 50% by weight or more.

According to a typical carbon nanotube synthesizing method, semiconductor-type carbon nanotubes having various kinds of chirality are synthesized concurrently. In production of the function layer 101, a plurality of semiconductor-type carbon nanotubes that have undergone a process of increasing a density of semiconductor-type carbon nanotubes having specific chirality in synthesized plurality of semiconductor-type carbon nanotubes may be used. As a method for increasing a density of semiconductor-type carbon nanotubes having specific chirality after synthesizing carbon nanotubes, a method such as a gel filtration technique, an ATPE method, or a selective polymer wrapping method can be used. Any of the methods may be used in production of the image sensor 100.

Note that not only a method for increasing a density of semiconductor-type carbon nanotubes having specific chirality after synthesizing carbon nanotubes, but also a method for selectively synthesizing semiconductor-type carbon nanotubes having specific chirality may be used. Examples of a method for selectively synthesizing semiconductor-type carbon nanotubes having specific chirality include (a) a method of selectively growing only semiconductor-type carbon nanotubes having specific chirality by changing a kind of catalyst for synthesis, a synthesis condition, or the like and (b) a method of precisely synthesizing semiconductor-type carbon nanotubes having specific chirality by using a carbon nanoring, which is a shortest carbon nanotube, as a template. By using a method for selectively synthesizing semiconductor-type carbon nanotubes having specific chirality, a proportion of metal-type carbon nanotubes among all synthesized carbon nanotubes can also be lowered.

A resonance wavelength can be freely selected as long as semiconductor-type carbon nanotubes having chirality achieving the target resonance wavelength are available. The resonance wavelength is, for example, selected on the basis of a wavelength of light entering the image sensor 100 such as modulated light used for distance measurement imaging. The wavelength of modulated light is, for example, selected from the following perspectives.

A first perspective for selecting the wavelength of modulated light is a sunlight intensity. Sunlight is partially absorbed in atmosphere and therefore attenuates in some wavelength ranges. A representative attenuated wavelength range is a range around 940 nanometers and a range from approximately 1350 nanometers to approximately 1450 nanometers. In a case where a wavelength at which sunlight strongly attenuates is used as the wavelength of modulated light, the modulated light can be easily identified even outdoor in the daytime, and therefore distance measurement accuracy can be increased. Examples of chirality of semiconductor-type carbon nanotubes having a resonance wavelength (e.g., a first resonance wavelength) in this range or close to this range are (9, 1), (9, 7), (11, 4), (12, 2), (12, 4), (10, 6), (13, 0), (11, 6), and (9, 8).

A second perspective for selecting the wavelength of modulated light is eye safe. Light of a wavelength range of 1400 nanometers or more is absorbed by an eye ball before entering a retina. Accordingly, laser light having a wavelength of 1400 nanometers or more has high safety for eyes and is called an eye-safe laser. Examples of chirality of semiconductor-type carbon nanotubes having a resonance wavelength (e.g., a first resonance wavelength) in this range or close to this range are (10, 6), (13, 0), (11, 6), (9, 8), (15, 1), (14, 3), (10, 8), (13, 3), (14, 1), (13, 5), and (12, 5).

A third perspective for selecting the wavelength of modulated light is availability of a light source. A laser is typically used as a light source of modulated light. Although a high-output laser can be intensity-modulated as it is, a low-output laser may be modulated and be amplified by an optical amplifier. According to such a configuration, a driving circuit can be simplified, and heat radiation is easier. For example, a wavelength range that can be used by a rare-earth-doped fiber amplifier among optical amplifiers is decided by an energy level of the rare earth.

An ytterbium-doped optical amplifier functions in a wavelength range from approximately 1025 nanometers to approximately 1075 nanometers. Examples of chirality of semiconductor-type carbon nanotubes having a resonance wavelength (e.g., a first resonance wavelength) in this range or close to this range are (7, 5), (11, 0), and (8, 1).

A praseodymium-doped optical amplifier functions in a wavelength range from approximately 1280 nanometers to approximately 1330 nanometers. Examples of chirality of semiconductor-type carbon nanotubes having a resonance wavelength (e.g., a first resonance wavelength) in this range or close to this range are (11, 1), (10, 5), and (8, 7).

An erbium-doped optical amplifier functions in a wavelength range from approximately 1530 nanometers to approximately 1535 nanometers. Examples of chirality of semiconductor-type carbon nanotubes having a resonance wavelength (e.g., a first resonance wavelength) in this range or close to this range are (13, 5) and (12, 5).

A reason why semiconductor-type carbon nanotubes are suitable as a photoelectric conversion material of the present embodiment lies not only on the presence of a resonance wavelength, but also on mobility of electric charges.

In the present embodiment, the function layer 101 functions as the channel region of the first modulation transistor Tm1 and the channel region of the second modulation transistor Tm2. Furthermore, according to the imaging method of the present embodiment, a drain current is modulation-controlled by periodically changing the gate voltage of the first modulation transistor Tm1 and the gate voltage of the second modulation transistor Tm2, as described later. As a frequency of modulation control which the drain current can follow becomes higher, for example, a modulation frequency of modulated light can be increased, and distance measurement accuracy can be increased. The frequency of modulation control which the drain current can follow becomes higher as mobility of a channel becomes higher. An upper limit of the frequency of modulation control which the drain current can follow is desirably higher than 10 MHz although the upper limit depends on usage.

According to quantum dots, a low-molecular organic semiconductor, and a polymer semiconductor used in a conventional photoelectric conversion element, mobility of electric charges is typically 1 cm²/V·s or less, and it is extremely hard for the frequency of modulation control which the drain current can follow to exceed 10 MHz.

As illustrated in FIG. 4, a semiconductor-type carbon nanotube is a cylindrical molecule. In a semiconductor-type carbon nanotube, a degree of freedom of movement of electric charges, that is, mobility of electric charges in an axial direction extending along an axis of the cylinder is high. A semiconductor-type carbon nanotube is a molecule having a certain degree of flexibility and therefore can exist in a curved state. Even in this case, a degree of freedom of movement of electric charges in an axial direction extending along an axis of the cylinder is high.

In a semiconductor-type carbon nanotube, mobility of electric charges in an axial direction extending along an axis of the cylinder is several thousand to ten thousand cm²/V·s or more. In the present embodiment, the function layer 101 contains a plurality of semiconductor-type carbon nanotubes. Even in the function layer 101 containing a plurality of semiconductor-type carbon nanotubes, mobility of 100 cm²/V·s can be achieved. This value of mobility is enough to make the frequency of modulation control which the drain current can follow equal to or more than 10 MHz.

In the function layer 101 containing a plurality of semiconductor-type carbon nanotubes, movement of electric charges in the function layer 101 is achieved by both of movement of electric charges in each of the semiconductor-type carbon nanotubes and movement of electric charges between semiconductor-type carbon nanotubes. Movement of electric charges between semiconductor-type carbon nanotubes is slower than movement of electric charges in each of the semiconductor-type carbon nanotubes. Accordingly, mobility of electric charges in the function layer 101 is affected by a length and layout of the plurality of semiconductor-type carbon nanotubes contained in the function layer 101.

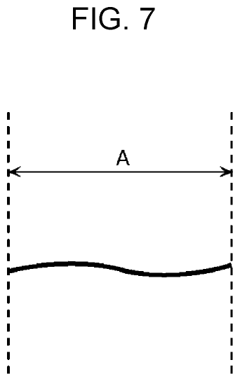

FIG. 7 is a schematic view for explaining a length of a semiconductor-type carbon nanotube. In a case where a semiconductor-type carbon nanotube exists in a curved state, the length of the semiconductor-type carbon nanotube in the present specification is not a distance along an axis of the cylinder of the semiconductor-type carbon nanotube but a linear distance between terminals, as illustrated in FIG. 7. That is, a length A illustrated in FIG. 7 is a length of the semiconductor-type carbon nanotube.

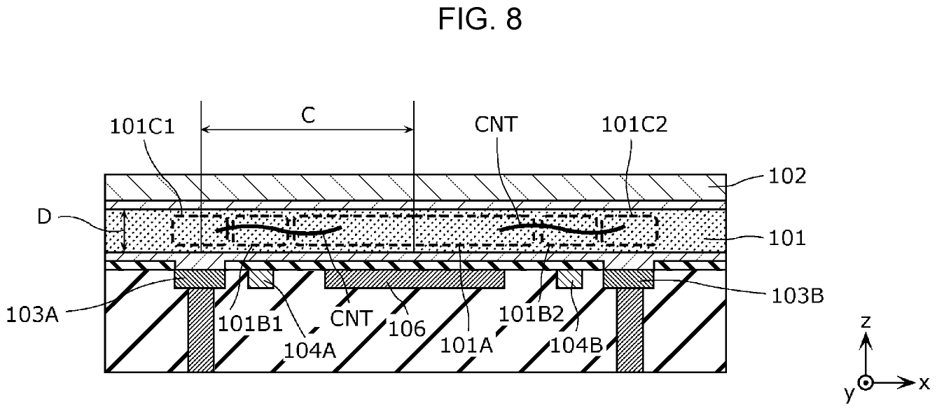

FIG. 8 is a schematic view for explaining a layout of the semiconductor-type carbon nanotubes in the function layer 101. The black thick lines indicated by CNT in the function layer 101 illustrated in FIG. 8 are semiconductor-type carbon nanotubes. Note that

FIG. 8 is a view for explaining semiconductor-type carbon nanotubes, and therefore illustration of some constituent elements of the pixel 10 is omitted. Furthermore, only some semiconductor-type carbon nanotubes among the plurality of semiconductor-type carbon nanotubes are illustrated.

As illustrated in FIG. 8, at least one of the plurality of semiconductor-type carbon nanotubes extends from the electric charge generating part 101A to the first electric charge exchange part 101C1. With this configuration, the second electric charges generated in the at least one semiconductor-type carbon nanotube can move to the first electric charge exchange part 101C1 just by moving through this semiconductor-type carbon nanotube without the need of movement of electric charges between semiconductor-type carbon nanotubes. This can increase mobility of electric charges in the function layer 101. As a result, it is possible to increase an upper limit of the frequency of modulation control.

Furthermore, at least one of the plurality of semiconductor-type carbon nanotubes may extend from the electric charge generating part 101A to the second electric charge exchange part 101C2.

In particular, in a case where an average length of the plurality of semiconductor-type carbon nanotubes is longer than a distance traversing the first transport modulation part 101B1 or the second transport modulation part 101B2 in a path extending from the electric charge generating part 101A toward the first electric charge exchange part 101C1 through the first transport modulation part 101B1 or a path extending from the electric charge generating part 101A toward the second electric charge exchange part 101C2 through to the second transport modulation part 101B2, a possibility that the second electric charges are modulation-controlled and move in a single semiconductor-type carbon nanotube is increased. In the present specification, the average length of the plurality of semiconductor-type carbon nanotubes is an average of the lengths A (see FIG. 7) of the plurality of semiconductor-type carbon nanotubes.

For example, the average length of the semiconductor-type carbon nanotubes may be √2 times larger than a width of the first control electrode 104A and the second control electrode 104B or more. In a case where the plurality of semiconductor-type carbon nanotubes are randomly oriented in the function layer 101, a possibility that a single semiconductor-type carbon nanotube traverses the first transport modulation part 101B1 and the second transport modulation part 101B2 is high in a case where the average length of the plurality of semiconductor-type carbon nanotubes is √2 times larger than the width of the first control electrode 104A and the second control electrode 104B or more.

Furthermore, for example, in a case where a proportion of semiconductor-type carbon nanotubes whose axis of the cylinder is parallel with a certain plane is high and a proportion of semiconductor-type carbon nanotubes whose axis of the cylinder is parallel with a direction perpendicular to the plane is low among the plurality of semiconductor-type carbon nanotubes in the function layer 101, mobility of electric charges in the function layer 101 is high in a direction parallel with the plane and is low in the direction perpendicular to the plane.

For example, the average length of the plurality of semiconductor-type carbon nanotubes may be longer than a thickness D of the function layer 101 illustrated in FIG. 8. With this configuration, axes of the cylinders of the plurality of semiconductor-type carbon nanotubes are more likely to be oriented in a direction perpendicular to the thickness direction of the function layer 101, as illustrated in FIG. 8. That is, the axes of the cylinders of the plurality of semiconductor-type carbon nanotubes are more likely to be oriented in a direction extending from the electric charge generating part 101A toward the first electric charge exchange part 101C1 through the first transport modulation part 101B1 and a direction extending from the electric charge generating part 101A toward the second electric charge exchange part 101C2 through the second transport modulation part 101B2. As a result, mobility of the second electric charges in a direction extending from the electric charge generating part 101A toward the first electric charge exchange part 101C1 through the first transport modulation part 101B1 and a direction extending from the electric charge generating part 101A toward the second electric charge exchange part 101C2 through the second transport modulation part 101B2 can be increased. It is therefore possible to increase an upper limit of the frequency of modulation control.

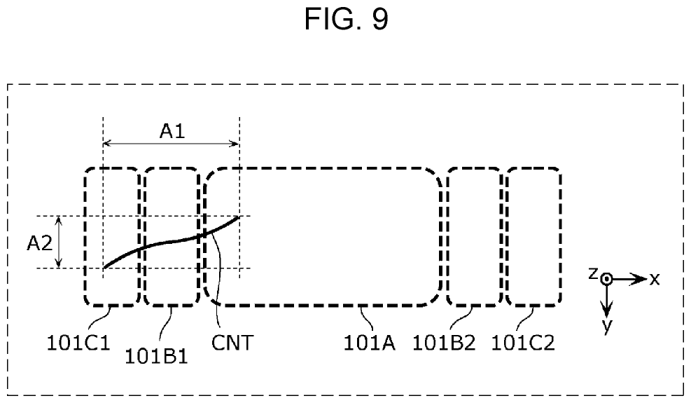

FIG. 9 is a view for explaining a length of a semiconductor-type carbon nanotube in top view. FIG. 9 illustrates a semiconductor-type carbon nanotube in a case where the function layer 101 is viewed in top view.

As illustrated in FIG. 9, a length of a semiconductor-type carbon nanotube along a direction in which the electric charge generating part 101A, the first transport modulation part 101B1, and the first electric charge exchange part 101C1 are arranged is referred to as A1. Meanwhile, a length of the semiconductor-type carbon nanotube in a direction perpendicular to the direction in which the electric charge generating part 101A, the first transport modulation part 101B1, and the first electric charge exchange part 101C1 are arranged is referred to as A2. For example, a proportion of semiconductor-type carbon nanotubes whose length A1 is longer than the length A2 may be larger than a proportion of semiconductor-type carbon nanotubes whose length A2 is longer than the length A1 among the plurality of semiconductor-type carbon nanotubes in the function layer 101. With this configuration, mobility of the second electric charges in a direction extending from the electric charge generating part 101A toward the first electric charge exchange part 101C1 through the first transport modulation part 101B1 and a direction extending from the electric charge generating part 101A toward the second electric charge exchange part 101C2 through the second transport modulation part 101B2 is increased. It is therefore possible to increase an upper limit of the frequency of modulation control.

Furthermore, as illustrated in FIG. 8, the thickness D of the function layer 101 is, for example, shorter than a distance C between the electric charge generating part 101A and the first electric charge exchange part 101C1. The distance C is a distance between a center of the electric charge generating part 101A and a center of the first electric charge exchange part 101C1. With this configuration, the thickness of the function layer 101 is shorter than a distance over which the second electric charges are moved from the electric charge generating part 101A to the first electric charge exchange part 101C1, and therefore the plurality of semiconductor-type carbon nanotubes are more likely to be located close to the first control electrode 104A. Accordingly, it becomes easy to control movement of the second electric charges in the first transport modulation part 101B1, and efficiency of collection of the second electric charges by the first collection electrode 103A is increased. For a similar reason, the thickness D of the function layer 101 may be shorter than a distance between the electric charge generating part 101A and the second electric charge exchange part 101C2.

Next, other materials contained in the function layer 101 are described.

In the function layer 101 constituted only by semiconductor-type carbon nanotubes, efficiency of taking out positive electric charges and negative electric charges generated in the function layer 101 is sometimes low. In this case, in a case where the function layer 101 contains an acceptor material in addition to the semiconductor-type carbon nanotubes, efficiency of taking out electric charges can be increased.

The acceptor material is a molecule having a function of extracting positive electric charges or negative electric charges generated in the semiconductor-type carbon nanotubes. The acceptor material is, for example, a molecule having a lowest unoccupied molecular orbital (LUMO) level lower than lowest energy of a conduction band of the semiconductor-type carbon nanotubes or a molecule having a highest occupied molecular orbital (HOMO) level higher than highest energy of a valence band of the semiconductor-type carbon nanotubes. For example, the former functions as an electron acceptor that extracts negative electric charges from the semiconductor-type carbon nanotubes, and the latter functions as a hole acceptor that extracts positive electric charges from the semiconductor-type carbon nanotubes.

Examples of the electron acceptor include fullerenes such as fullerene (C60 and C70), phenyl-C₆₁-butyric acid methyl ester (PCBM), 2a-Aza-1,2(2a)-homo-1,9-seco[5,6]fullerene-C60-Ih-1,9-dione, 2a[(4-hexyloxy)-3-methoxyphenyl]methyl](KLOC-6), and fullerene-functionalized flavin (FC60) represented by the following structural formula (1).

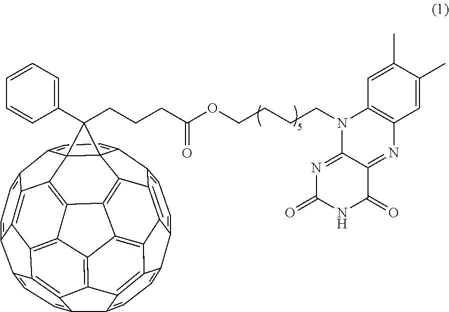

Examples of the hole acceptor include P3HT (poly-3-hexylthiophene) polymer.

In a case where an electron acceptor is used as the acceptor material, positive electric charges remain in the semiconductor-type carbon nanotubes, and in a case where a hole acceptor is used as the acceptor material, negative electric charges remain in the semiconductor-type carbon nanotubes.

In the present embodiment, an electron acceptor may be used or a hole acceptor may be used. For example, an electron acceptor is used in a case where positive electric charges are collected by the first collection electrode 103A and the second collection electrode 103B, and a hole acceptor is used in a case where negative electric charges are collected by the first collection electrode 103A and the second collection electrode 103B. That is, the acceptor material receives the first electric charges that are not collected by the first collection electrode 103A and the second collection electrode 103B.

This is because mobility of electric charges in the semiconductor-type carbon nanotubes is high, and therefore modulation control of a higher frequency can be performed by applying modulation on electric charges remaining in the semiconductor-type carbon nanotubes when movement of electric charges in the function layer 101 is modulation-controlled by a voltage applied to the first control electrode 104A and a voltage applied to the second control electrode 104B.

In the present embodiment, electric charges generated in the semiconductor-type carbon nanotubes can be moved in the semiconductor-type carbon nanotubes. That is, a movement time of electric charges from a photoelectric conversion region to an electric charge transport layer, which is needed in the configuration of U.S. Patent Application Publication No. 2019/0252455, becomes unnecessary. It is therefore possible to remove one of factors restricting an upper limit of a frequency of modulation control.

The function layer 101 may be a mixed film in which the plurality of semiconductor-type carbon nanotubes and the acceptor material are evenly distributed or may have a multilayer structure in which the plurality of semiconductor-type carbon nanotubes and the acceptor material are laminated. In a case where the acceptor material is present close to a semiconductor-type carbon nanotube that has absorbed light, separation of electric charges is performed more speedily. From the perspective of making separation of electric charges generated in the semiconductor-type carbon nanotubes faster, the function layer 101 may be a mixed film in which the plurality of semiconductor-type carbon nanotubes and the acceptor material are mixed.

A molecule used for the acceptor material may be a molecule such as FC60 obtained by linking a molecular structure part (flavin in the example of FC60) adsorbed to a semiconductor-type carbon nanotube and a molecular structure part (fullerene in the example of FC60) functioning as an acceptor. This can increase a proportion of the acceptor material present close to the semiconductor-type carbon nanotubes.

In the function layer 101, the acceptor material is, for example, contained in the electric charge generating part 101A. The acceptor material need not necessarily be contained in the first transport modulation part 101B1, the second transport modulation part 101B2, the first electric charge exchange part 101C1, and the second electric charge exchange part 101C2. Furthermore, a density of the acceptor material in the first transport modulation part 101B1, the second transport modulation part 101B2, the first electric charge exchange part 101C1, and the second electric charge exchange part 101C2 may be lower than a density of the acceptor material in the electric charge generating part 101A. With this configuration, even in a case where the first transport modulation part 101B1, the second transport modulation part 101B2, the first electric charge exchange part 101C1, and the second electric charge exchange part 101C2 are irradiated with unintended light, positive electric charges and negative electric charges generated in the semiconductor-type carbon nanotubes present in the first transport modulation part 101B1, the second transport modulation part 101B2, the first electric charge exchange part 101C1, and the second electric charge exchange part 101C2 are more likely to disappear by reunion without being extracted from the semiconductor-type carbon nanotubes. The electric charges generated in the first transport modulation part 101B1, the second transport modulation part 101B2, the first electric charge exchange part 101C1, and the second electric charge exchange part 101C2 are not influenced by modulation control and therefore becomes noise when collected by the first collection electrode 103A and the second collection electrode 103B, and, for example, decreases distance measurement accuracy. Since it becomes more likely that the positive electric charges and the negative electric charges generated in the first transport modulation part 101B1, the second transport modulation part 101B2, the first electric charge exchange part 101C1, and the second electric charge exchange part 101C2 disappear by reunion, noise can be reduced, and for example, distance measurement accuracy can be improved.

Furthermore, the function layer 101 may contain a material other than the semiconductor-type carbon nanotubes and the acceptor material. For example, carbon nanotubes are easy to aggregate by themselves. Furthermore, aggregated carbon nanotubes are sometimes hard to handle in a production process of the image sensor 100.

In view of this, a plurality of semiconductor-type carbon nanotubes coated with a dispersant may be used for the function layer 101. Examples of the dispersant include polymers such as polyfluorene (PFO) and polydodecylfluorene (PFD), low-molecular organic substances such as flavin derivatives and pyrene derivatives, surfactants such as sodium dodecyl sulfate (SDS) and sodium dodecylbenzenesulfonate (SDBS), and cellulose nanofibers. Note that semiconductor-type carbon nanotubes and a dispersant (selective dispersant) having a function of selectively adsorbing to semiconductor-type carbon nanotubes having specific chirality such as PFO or FC12 represented by the following structural formula (2) among polymers and flavin derivatives may be used.

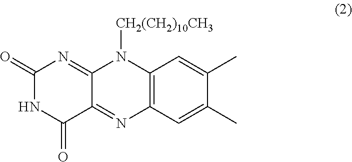

### 2-2. Transparent Electrode

The transparent electrode 102 has a function of collecting the first electric charges, which are positive electric charges or negative electric charges generated in the electric charge generating part 101A of the function layer 101. The “transparent” of the transparent electrode 102 means having transparency to a wavelength at which the electric charge generating part 101A has sensitivity of photoelectric conversion. For example, the transparent electrode 102 has transparency to a wavelength of modulated light for distance measurement imaging. Accordingly, the transparent electrode 102 need not have transparency to wavelengths other than the wavelength at which the electric charge generating part 101A has sensitivity of photoelectric conversion, for example, to wavelengths other than the wavelength of modulated light.

Examples of a material of which the transparent electrode 102 is made include indium tin oxide (ITO), zinc oxide, IGZO (indium, gallium, zinc oxide), and few-layer graphene.

As illustrated in FIG. 3, the transparent electrode 102 is located above the function layer 101. The transparent electrode 102 corresponds to the terminal Ntr in FIGS. 1 and 2 and is connected to the photoelectric conversion element Dpv and the voltage control unit 21. Furthermore, the photoelectric conversion element Dpv corresponds to the electric charge generating part 101A included in the function layer 101, as described above. Accordingly, the transparent electrode 102 is electrically connected to the function layer 101 and the voltage control unit 21 (not illustrated in FIG. 3).

For example, the transparent electrode 102 and the voltage control unit 21 may be connected by an electrode pad or the like provided on the semiconductor substrate 150 or may be connected by a bonding wire or the like.

The function layer 101 and the transparent electrode 102 may be connected in direct contact with each other or may be electrically connected with another layer in which electric charges are movable interposed therebetween. In the example illustrated in FIG. 3, a block layer 122 is located between the function layer 101 and the transparent electrode 102. That is, each of the pixels 10 may have the block layer 122.

The block layer 122 is made of a material that allows passage of the first electric charges of a polarity collected by the transparent electrode 102 more than electric charges of an opposite polarity. For example, in a case where the first electric charges are positive electric charges, the block layer 122 is made of a material such as a compound of poly(3,4-ethylenedioxythiophene) and polystyrene sulfonate (PEDOT:PSS), and in a case where the first electric charges are negative electric charges, the block layer 122 is made of a material such as C60.

In a case where each of the pixels 10 has the block layer 122, inflow of electric charges from the transparent electrode 102 to the function layer 101 can be suppressed, and dark-current noise can be lessened.

### 2-3. Collection Electrode

The first collection electrode 103A and the second collection electrode 103B have a function of collecting the second electric charges that are not collected by the transparent electrode 102, that is, the second electric charges of a polarity opposite to the first electric charges collected by the transparent electrode 102 among the positive electric charges and the negative electric charges generated in the function layer 101. More specifically, the first collection electrode 103A collects second electric charges that are not collected by the transparent electrode 102 among electric charges generated in the electric charge generating part 101A of the function layer 101 via the first electric charge exchange part 101C1. The second collection electrode 103B collects second electric charges that are not collected by the transparent electrode 102 among electric charges generated in the electric charge generating part 101A of the function layer 101 via the second electric charge exchange part 101C2.

The first collection electrode 103A and the second collection electrode 103B are made of an electrically-conductive material. Examples of the electrically-conductive material include metals such as aluminum and copper, metal nitrides, and polysilicon given electric conductivity by being doped with impurities.

As illustrated in FIG. 3, the first collection electrode 103A and the second collection electrode 103B face the transparent electrode 102 and are located below the function layer 101. In top view, the first collection electrode 103A overlaps the first electric charge exchange part 101C1, and the second collection electrode 103B overlaps the second electric charge exchange part 101C2. Furthermore, in top view, the first collection electrode 103A and the second collection electrode 103B overlap the light-shielding body 114. The first collection electrode 103A and the second collection electrode 103B are provided on the interlayer insulating layer 130. Upper surfaces of the first collection electrode 103A, the second collection electrode 103B, the first control electrode 104A, the second control electrode 104B, and the bias electrode 106 are located on an identical plane.

The first collection electrode 103A and the second collection electrode 103B correspond to the terminal Nc1 and the terminal Nc2 in FIG. 2, respectively. In FIG. 2, the terminal Nc1 is connected to the drain of the first modulation transistor Tm1 and the first electric charge accumulation region Nfd1, and the terminal Nc2 is connected to the drain of the second modulation transistor Tm2 and the second electric charge accumulation region Nfd2. As described above, the drain of the first modulation transistor Tm1 and the drain of the second modulation transistor Tm2 correspond to parts of the function layer 101, specifically, the first electric charge exchange part 101C1 and the second electric charge exchange part 101C2, respectively. Furthermore, the first electric charge accumulation region Nfd1 in FIG. 2 corresponds to the first electric charge accumulation region 105A, and the second electric charge accumulation region Nfd2 in FIG. 2 corresponds to the second electric charge accumulation region 105B although details thereof will be described later. Accordingly, the first collection electrode 103A is electrically connected to the first electric charge exchange part 101C1 of the function layer 101 and the first electric charge accumulation region 105A. Furthermore, the second collection electrode 103B is electrically connected to the second electric charge exchange part 101C2 of the function layer 101 and the second electric charge accumulation region 105B.

The first collection electrode 103A and the first electric charge accumulation region 105A are connected by a via wire 131A provided in the interlayer insulating layer 130 provided on the semiconductor substrate 150. Furthermore, the second collection electrode 103B and the second electric charge accumulation region 105B are connected by a via wire 131B provided in the interlayer insulating layer 130.

The function layer 101 and the first collection electrode 103A and the second collection electrode 103B may be connected in direct contact with each other or may be electrically connected with another layer in which electric charges are movable interposed therebetween. In the example illustrated in FIG. 3, a block layer 121 is located between the function layer 101 and the first collection electrode 103A and the second collection electrode 103B. That is, each of the pixels 10 may have the block layer 121.

The block layer 121 is made of a material that allows passage of the second electric charges of a polarity collected by the first collection electrode 103A and the second collection electrode 103B more than electric charges of an opposite polarity. For example, in a case where the second electric charges are positive electric charges, the block layer 121 is made of a material such as PEDOT:PSS, and in a case where the second electric charges are negative electric charges, the block layer 121 is made of a material such as C60.

In a case where each of the pixels 10 has the block layer 121, inflow of electric charges from the first collection electrode 103A and the second collection electrode 103B to the function layer 101 can be suppressed, and dark-current noise can be lessened.

### 2-4. Control Electrode

The first control electrode 104A and the second control electrode 104B control movement, toward the first collection electrode 103A and the second collection electrode 103B, of the second electric charges to be collected by the first collection electrode 103A and the second collection electrode 103B among positive electric charges and negative electric charges generated in the electric charge generating part 101A. Specifically, the first control electrode 104A has a function of changing a proportion of second electric charges that move from the electric charge generating part 101A to the first electric charge exchange part 101C1 and to be collected by the first collection electrode 103A among positive electric charges and negative electric charges generated in the electric charge generating part 101A of the function layer 101 by changing a voltage of the first transport modulation part 101B1. The second control electrode 104B has a function of changing a proportion of second electric charges that move from the electric charge generating part 101A to the second electric charge exchange part 101C2 and to be collected by the second collection electrode 103B among positive electric charges and negative electric charges generated in the electric charge generating part 101A of the function layer 101 by changing a voltage of the second transport modulation part 101B2. The first control electrode 104A and the second control electrode 104B modulation-control movement of the second electric charges by changing a proportion of the second electric charges that move from the electric charge generating part 101A to the first electric charge exchange part 101C1 and the second electric charge exchange part 101C2 at constant time intervals by temporal changes of voltages supplied to the first control electrode 104A and the second control electrode 104B. In other words, the first control electrode 104A and the second control electrode 104B temporally changes a proportion of second electric charges to be accumulated in the first electric charge accumulation region 105A and the second electric charge accumulation region 105B among the second electric charges generated in the electric charge generating part 101A.

The first control electrode 104A and the second control electrode 104B are made of an electrically-conductive material. Examples of the electrically-conductive material include metals such as aluminum and copper, metal nitrides, and polysilicon given electric conductivity by being doped with impurities.

The first control electrode 104A and the second control electrode 104B face the transparent electrode 102 and are located below the function layer 101. In top view, the first control electrode 104A overlaps the first transport modulation part 101B1, and the second control electrode 104B overlaps the second transport modulation part 101B2. Furthermore, in top view, the first control electrode 104A and the second control electrode 104B are located so as to sandwich the electric charge generating part 101A. Furthermore, in top view, the first control electrode 104A and the second control electrode 104B overlap the light-shielding body 114. Furthermore, the first control electrode 104A and the second control electrode 104B are disposed on the interlayer insulating layer 130.

Furthermore, the first control electrode 104A and the second control electrode 104B are located between the first collection electrode 103A and the second collection electrode 103B. The first control electrode 104A is adjacent to the first collection electrode 103A. The second control electrode 104B is adjacent to the second collection electrode 103B. A distance between the first control electrode 104A and the first collection electrode 103A is identical to a distance between the second control electrode 104B and the second collection electrode 103B. The bias electrode 106, which will be described later, is disposed between the first control electrode 104A and the second control electrode 104B.

The first control electrode 104A and the second control electrode 104B correspond to the terminal Ng1 connected to the gate of the first modulation transistor Tm1 and the terminal Ng2 connected to the gate of the second modulation transistor Tm2 in FIGS. 1 and 2, respectively. The terminal Ng1 and the terminal Ng2 are connected to the control mechanism 23A and the control mechanism 23B, respectively and are configured so that voltages thereof are changed temporally. As described above, the first transport modulation part 101B1 included in the function layer 101 corresponds to the channel region of the first modulation transistor Tm1, and therefore a portion between the first control electrode 104A and the function layer 101 corresponds to the gate of the first modulation transistor Tm1. Furthermore, the second transport modulation part 101B2 included in the function layer 101 corresponds to the channel region of the second modulation transistor Tm2, and therefore a portion between the second control electrode 104B and the function layer 101 corresponds to the gate of the second modulation transistor Tm2. Furthermore, the first control electrode 104A and the second control electrode 104B are connected to the control mechanism 23A and the control mechanism 23B (not illustrated in FIG. 3), respectively.

The portion between the first control electrode 104A and the function layer 101 and the portion between the second control electrode 104B and the function layer 101 may, for example, have a structure in which no direct current flows. With this configuration, collection of the second electric charges by the first control electrode 104A and the second control electrode 104B can be suppressed. In the example illustrated in FIG. 3, an insulating film 123 is disposed between the function layer 101 and the first control electrode 104A and the second control electrode 104B. That is, each of the pixels 10 has the insulating film 123 between the function layer 101 and the first control electrode 104A and the second control electrode 104B. The insulating film 123 is not disposed on the first collection electrode 103A and the second collection electrode 103B. Accordingly, the block layer 121 has steps. The insulating film 123 is, for example, made of an insulating material such as silicon dioxide.

Although FIG. 3 illustrates a case where an upper surface of the block layer 121 is flat, that is, an example in which a thickness of the block layer 121 varies depending on a position, this configuration is not essential. The block layer 121 may have an almost constant thickness and may have a shape having steps according to the presence or absence of the insulating film 123. Members such as the function layer 101 located above the block layer 121 may have a shape other than a parallel flat-plate shape because of the steps.

The thickness of the insulating film 123 may be approximately several nanometers to several tens of nanometers. Meanwhile, the thickness of the function layer 101 may be several hundreds of nanometers or more. In a case where the thickness of the function layer 101 is smaller than the thickness of the insulating film 123, steps on an upper surface of the function layer 101 created by the presence or absence of the insulating film 123 can be made smaller than steps on a lower surface of the function layer 101 due to a planarizing effect during film formation of the function layer 101.

Note that the insulating film 123 need not necessarily be provided. For example, a DC current flowing between the function layer 101 and the first control electrode 104A and the second control electrode 104B may be suppressed by using a Schottky barrier.

### 2-5. Electric Charge Accumulation Region and Semiconductor Substrate

The semiconductor substrate 150 is located below the function layer 101. The semiconductor substrate 150 is a substrate that supports constituent elements of the pixels 10 such as the function layer 101. The semiconductor substrate 150 is, for example, a single-crystal silicon substrate. The semiconductor substrate 150 includes the first electric charge accumulation region 105A and the second electric charge accumulation region 105B.

The first electric charge accumulation region 105A and the second electric charge accumulation region 105B are connected to the first collection electrode 103A and the second collection electrode 103B by the via wire 131A and the via wire 131B, respectively. The first electric charge accumulation region 105A and the second electric charge accumulation region 105B have a function of accumulating electric charges collected by the first collection electrode 103A and the second collection electrode 103B, respectively. In the present embodiment, it is also possible to employ a configuration in which only one of the first electric charge accumulation region 105A and the second electric charge accumulation region 105B is provided and electric charges collected by the first collection electrode 103A or the second collection electrode 103B that is not connected to the one electric charge accumulation region are discarded to a constant voltage line or the like without being accumulated.

The first electric charge accumulation region 105A and the second electric charge accumulation region 105B are, for example, disposed on a plane different from the function layer 101. In the present embodiment, the first electric charge accumulation region 105A and the second electric charge accumulation region 105B are provided in the semiconductor substrate 150. The function layer 101 is laminated above the semiconductor substrate 150. In other words, the first electric charge accumulation region 105A and the second electric charge accumulation region 105B are located below the function layer 101. This arrangement overcomes a problem that the electric charge generating part 101A, which is a photoelectric conversion region, and the first electric charge accumulation region 105A and the second electric charge accumulation region 105B, which are electric charge accumulation parts, limit each other's sizes. The first electric charge accumulation region 105A and the second electric charge accumulation region 105B are, for example, N-type or P-type impurity regions in the semiconductor substrate 150.

The first electric charge accumulation region 105A and the second electric charge accumulation region 105B correspond to at least part of the first electric charge accumulation region Nfd1 and at least part of the second electric charge accumulation region Nfd2 in FIG. 2, respectively.

The semiconductor substrate 150 may include the first reset transistor Trl, the second reset transistor Tr2, the first amplifier transistor Tg1, the second amplifier transistor Tg2, the first transfer transistor Tt1, the second transfer transistor Tt2, and the like in FIG. 2 (not illustrated). The first electric charge accumulation region 105A is connected to the drain of the first reset transistor Tr1 and the gate of the first amplifier transistor Tg1, and the second electric charge accumulation region 105B is connected to the drain of the second reset transistor Tr2 and the gate of the second amplifier transistor Tg2.

Furthermore, the semiconductor substrate 150 may include peripheral circuits such as the electric charge amount measuring device 31A and the electric charge amount measuring device 31B. Alternatively, the semiconductor substrate 150 may be configured to be electrically connectable to peripheral circuits such as the electric charge amount measuring device 31A and the electric charge amount measuring device 31B provided on another semiconductor substrate or the like.

The image sensor 100 including the semiconductor substrate 150 can be created by a normal semiconductor integrated circuit production process by using a single-crystal silicon substrate or the like.

### [2-6. Other Constituent Elements]

Each of the pixels 10 of the image sensor 100 may have other constituent elements in addition to the constituent elements described above.

For example, as illustrated in FIG. 3, each of the pixels 10 may have the bias electrode 106. The bias electrode 106 is located below the function layer 101. The bias electrode 106 faces the transparent electrode 102 with the electric charge generating part 101A interposed therebetween. The bias electrode 106 is located between the first control electrode 104A and the second control electrode 104B. The bias electrode 106 is provided on the interlayer insulating layer 130. The insulating film 123 is disposed between the bias electrode 106 and the function layer 101. This suppresses exchange of electric charges between the bias electrode 106 and the function layer 101, thereby making it possible to suppress collection of the second electric charges by the bias electrode 106.

The bias electrode 106 corresponds to the terminal Nbias in FIGS. 1 and 2. Furthermore, a part of the insulating film 123 corresponds to the bias application capacitor Cbias in FIG. 2. By giving a voltage difference between the bias electrode 106 and the transparent electrode 102, an electric field can be generated in the electric charge generating part 101A of the function layer 101. In a case where an electric field is present inside the electric charge generating part 101A, positive electric charges and negative electric charges become easy to be separated, and disappearance of electric charges caused by reunion can be suppressed.

The bias electrode 106 is made of an electrically-conductive material. Examples of the electrically-conductive material include metals such as aluminum and copper, metal nitrides, and polysilicon given electric conductivity by being doped with impurities.

Note that a sufficient electric field can be generated inside the electric charge generating part 101A by the first control electrode 104A and the second control electrode 104B depending on a device design, a driving method, and an intended purpose of use. In this case, the bias electrode 106 need not necessarily be provided.

Furthermore, for example, as illustrated in FIG. 3, each of the pixels 10 may have an on-chip lens 111 and the light-shielding body 114. The on-chip lens 111 is an example of a lens.

The on-chip lens 111 is located above the transparent electrode 102. The on-chip lens 111 has a function of focusing light onto the electric charge generating part 101A of the function layer 101. The on-chip lens 111 allows light reaching the light-shielding body 114, which will be described later, to be guided to the electric charge generating part 101A that is not shielded from light by the light-shielding body 114. This allows the electric charge generating part 101A to be irradiated with more light, thereby increasing an amount of signal electric charges and improving sensitivity. Accordingly, for example, distance measurement accuracy is increased.

The light-shielding body 114 is located between the transparent electrode 102 and the on-chip lens 111. In top view, the light-shielding body 114 is located outside the electric charge generating part 101A and overlaps the first transport modulation part 101B1, the second transport modulation part 101B2, the first electric charge exchange part 101C1, and the second electric charge exchange part 101C2. The light-shielding body 114 has a function of preventing the function layer 101 other than the electric charge generating part 101A from being irradiated with light. For example, in a case where the first transport modulation part 101B1, the second transport modulation part 101B2, the first electric charge exchange part 101C1, or the second electric charge exchange part 101C2 is irradiated with light and electric charges are generated in the part irradiated with light, the generated electric charges are collected by the first collection electrode 103A or the second collection electrode 103B without being subjected to modulation control, and for example, become a signal component that does not depend on a phase of modulated light and decrease distance measurement accuracy.

Accordingly, the light-shielding body 114 may cover at least upper surfaces of the first collection electrode 103A and the second collection electrode 103B and may further cover upper surfaces of the first control electrode 104A and the second control electrode 104B. This can suppress occurrence of electric charges that are not subjected to modulation control. As a result, for example, a signal component of light other than the modulated light can be decreased, and distance measurement accuracy is increased.

As the light-shielding body 114, for example, a highly-light-reflecting body such as a metal is used. Alternatively, as the light-shielding body 114, a highly-light-absorbing body such as carbon may be used or a combination of a highly-light-reflecting body and a highly-light-absorbing body may be used.

Furthermore, for example, each of the pixels 10 may have a filter layer 112, as illustrated in FIG. 3. The filter layer 112 is located above the transparent electrode 102. Furthermore, the filter layer 112 is located between the light-shielding body 114 and the on-chip lens 111. An insulating protection layer 113 made of a transparent insulating material is disposed between the filter layer 112 and the transparent electrode 102.

The filter layer 112 allows passage of modulated light used for distance measurement whose intensity changes periodically and attenuates light other than the modulated light. As the filter layer 112, a bandpass filter and a long-path filter that have a dielectric multilayer film, color glass that absorbs light other than the modulated light, and the like are used.

In a case where the filter layer 112 is provided, light other than the modulated light attenuates, and a signal component of light other than the modulated light can be decreased, and distance measurement accuracy improves accordingly. Note that the filter layer 112 need not necessarily be provided. Furthermore, for example, a filter like the one described above may be disposed outside the image sensor 100.

### 3. Other Structure of Pixel

According to the above configuration of the pixel 10, the first control electrode 104A, the second control electrode 104B, and the bias electrode 106 are provided on the interlayer insulating layer 130, and upper surfaces of the first collection electrode 103A, the second collection electrode 103B, the first control electrode 104A, the second control electrode 104B, and the bias electrode 106 are located on an identical plane. However, this configuration is not restrictive. For example, the first control electrode 104A, the second control electrode 104B, and the bias electrode 106 may be provided in the interlayer insulating layer 130.

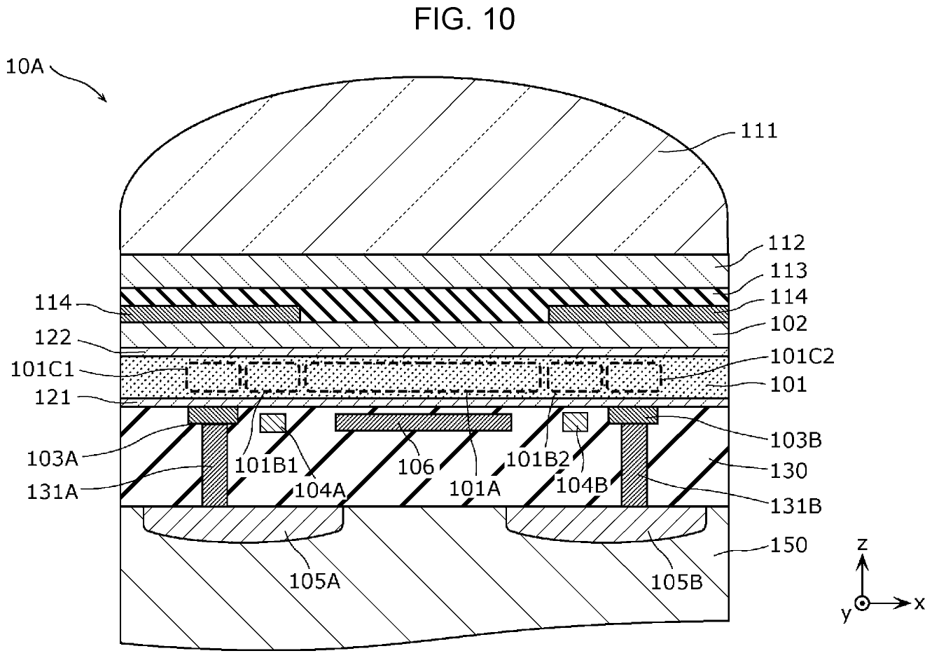

FIG. 10 is a cross-sectional view schematically illustrating a device structure of a pixel 10A according to another example of the present embodiment. The image sensor 100 according to the present embodiment may include pixels 10A instead of the pixels 10.

As illustrated in FIG. 10, in the pixel 10A, the first control electrode 104A, the second control electrode 104B, and the bias electrode 106 are provided in the interlayer insulating layer 130. That is, the interlayer insulating layer 130 is located between the function layer 101 and the first control electrode 104A, the second control electrode 104B, and the bias electrode 106. With this configuration, even in a case where the insulating film 123 is not disposed between the function layer 101 and the first control electrode 104A, the second control electrode 104B, and the bias electrode 106, movement of electric charges between the function layer 101 and the first control electrode 104A, the second control electrode 104B, and the bias electrode 106 is suppressed by the interlayer insulating layer 130.

Furthermore, since upper surfaces of the first collection electrode 103A, the second collection electrode 103B, and the interlayer insulating layer 130 are located on an identical plane, the block layer 121 laminated on the interlayer insulating layer 130 has no step. This makes it easy to uniformly laminate the block layer 121 and further makes it easy to uniformly laminate the function layer 101 on the block layer 121. Furthermore, even in a case where the pixel 10A does not include the block layer 121, it is easy to uniformly laminate the function layer 101 on the interlayer insulating layer 130.

### 4. Imaging Operation

Next, an example of operation of imaging using the image sensor 100 is described with reference to FIGS. 1 to 3. An order of steps described below is an example and may be changed as appropriate as long as the present embodiment can be implemented.

In distance measurement imaging using the image sensor 100, for example, steps 1 to 6 below are performed.

### [4-1. Step 1: Irradiation of Modulated Light]

In step 1, an external light source emits modulated light. Specifically, the external light source generates modulated light whose intensity changes at a predetermined frequency and emits the modulated light toward a subject.

### 4-2. Step 2: Initialization

In step 2, electric charges accumulated in the first electric charge accumulation region Nfd1 and the second electric charge accumulation region Nfd2 are reset.

The control mechanism 41 shifts the channel of the first reset transistor Tr1 and the channel of the second reset transistor Tr2 to a conduction state in a state where the electric charge accumulation region reset mechanism 24 is applying a predetermined voltage to the terminal NrL and the terminal NrR. In this way, electric charges accumulated in the first electric charge accumulation region Nfd1 and the second electric charge accumulation region Nfd2 are removed, and the first electric charge accumulation region Nfd1 and the second electric charge accumulation region Nfd2 are set to a preset voltage Vinil and a preset voltage V_ini2, respectively. As described above, the first electric charge accumulation region 105A corresponds to the first electric charge accumulation region Nfd1, and the second electric charge accumulation region 105B corresponds to the second electric charge accumulation region Nfd2.

A value of the voltage V_ini1 and a value of the voltage V_ini2 are decided on the basis of a polarity of electric charges collected by the first collection electrode 103A and the second collection electrode 103B. For example, in a case where the first collection electrode 103A and the second collection electrode 103B collect positive electric charges, the voltage V_ini1 and the voltage V_ini2 are set lower than the voltage V_tr. In a case where negative electric charges are collected by the first collection electrode 103A and the second collection electrode 103B, the voltage V_inil and the voltage V_ini2 are set higher than the voltage V tr.

### 4-3. Step 3: Application of Bias Voltage

In step 3, a voltage is applied to the terminal Ntr and the terminal Nbias that sandwich the photoelectric conversion element Dpv.

The voltage control unit 21 and the voltage control unit 22 apply the preset voltage V_tr and the preset voltage V_bias to the terminal Ntr corresponding to the transparent electrode 102 and the terminal Nbias corresponding to the bias electrode 106, respectively. In the present embodiment, normally, the voltage V_tr and the voltage V bias are different values.

For example, in a case where the voltage V_tr is higher than the voltage V_bias, positive electric charges generated in the photoelectric conversion element Dpv corresponding to the electric charge generating part 101A of the function layer 101 move to the terminal Nbias side, and negative electric charges generated in the photoelectric conversion element Dpv move to the terminal Ntr side. In a case where a voltage relationship is opposite to that described above, the positive electric charges and the negative electric charges move to opposite sides. In the present embodiment, the voltage V_tr may be higher or the voltage V_bias may be higher. As described earlier, for example, electric charges of a polarity extracted by the acceptor material among the positive electric charges and the negative electric charges generated in the semiconductor-type carbon nanotubes move to the terminal Ntr side. In this way, reunion of the positive electric charges and the negative electric charges generated in the semiconductor-type carbon nanotubes is suppressed.

In the present embodiment, an example in which the voltage V_tr is higher than the voltage V_bias is described below. This case corresponds to a case where the second electric charges are positive electric charges and the function layer 101 includes an electron acceptor.

### 4-4. Step 4: Exposure

In step 4, the modulated light enters the image sensor 100. That is, exposure to light is performed.

Reflected light or scattered light of the modulated light with which the subject was irradiated in Step 1 is focused by the on-chip lens 111 and enters the photoelectric conversion element Dpv. The entry of the light continues at least until readout in Step 6 starts.

### 4-5-1. Step 5A: Accumulation of Electric Charges in First Electric Charge Accumulation Region

In step 5A, the second electric charges generated in the photoelectric conversion element Dpv are accumulated in the first electric charge accumulation region Nfd1.

The control mechanism 23A applies a voltage Vonl that shifts the first modulation transistor Tm1 into a conduction state to the terminal Ng1 corresponding to the first control electrode 104A. Concurrently, the control mechanism 23B applies a voltage V_off2 that shifts the second modulation transistor Tm2 into a cut-off state to the terminal Ng2 corresponding to the second control electrode 104B. This causes the second electric charges to move to and be collected by the terminal Nc1 corresponding to the first collection electrode 103A and then be accumulated in the first electric charge accumulation region Nfd1. Details of movement of the electric charges will be described later.

The application of the voltages in step 5A is maintained for a predetermined period. For example, a period from start to end of step 5A is set by a user of the image sensor 100, for example, on the basis of a cycle of the emitted modulated light.

### 4-5-2. Step 5B: Accumulation of Electric Charge in Second Electric Charge Accumulation Region

In step 5B, the second electric charges generated in the photoelectric conversion element Dpv are accumulated in the second electric charge accumulation region Nfd2.

The control mechanism 23A applies a voltage V_off1 that shifts the first modulation transistor Tm1 into a cut-off state to the first control electrode 104A. Concurrently, the control mechanism 23B applies a voltage Von2 that shifts the second modulation transistor Tm2 into a conduction state to the second control electrode 104B. This causes the second electric charges to move to and be collected to the terminal Nc2 corresponding to the second collection electrode 103B and then be accumulated in the second electric charge accumulation region Nfd2. Details of movement of the electric charges will be described later.

The application of the voltages in step 5B is maintained for a predetermined period. For example, a period from start to end of step 5B is set by a user of the image sensor 100, for example, on the basis of a cycle of the emitted modulated light.

### 4-5-3. Repetition of Step 5A and Step 5B

Step 5A and step 5B are alternately repeated a predetermined number of times. The predetermined number of times is set in accordance with an intended purpose of use, target sensitivity, a surrounding environment, and the like.

### 4-6. Step 6: Readout

In step 6, a signal corresponding to an amount of electric charges accumulated in the first electric charge accumulation region Nfd1 and a signal corresponding to an amount of electric charges accumulated in the second electric charge accumulation region Nfd2 are read out.

Voltages corresponding to the amounts of electric charges accumulated in the first electric charge accumulation region Nfd1 and the second electric charge accumulation region Nfd2 are applied to the gate of the first amplifier transistor Tg1 and the gate of the second amplifier transistor Tg2. Furthermore, the control mechanism 51 applies a voltage V_ontr that shifts the first transfer transistor Tt1 and the second transfer transistor Tt2 into a conduction state to the terminal NtrL and the terminal NtrR of the pixel 10 of a row for which the readout is performed in a state where the voltage control unit 25 is applying a predetermined voltage to the terminal NgR and the terminal NgL. In this way, output of the first amplifier transistor Tg1 and output of the second amplifier transistor Tg2 according to the amount of electric charges accumulated in the first electric charge accumulation region Nfd 1 and the amount of electric charges accumulated in the second electric charge accumulation region Nfd2 are input to the electric charge amount measuring device 31A and the electric charge amount measuring device 31B. The electric charge amount measuring device 31A and the electric charge amount measuring device 31B measure the amount of electric charges accumulated in the first electric charge accumulation region Nfd 1 and the amount of electric charges accumulated in the second electric charge accumulation region Nfd2 on the basis of the input. The measured amounts of electric charges are, for example, read out by a readout circuit or the like.

### 5. Operation Principle

Next, how electric charges in the image sensor 100 behave and a distance measurement principle in the imaging operation are described.

In step 4 described above, when the modulated light enters the electric charge generating part 101A of the function layer 101 and the modulated light is absorbed by the semiconductor-type carbon nanotubes in the function layer 101, positive electric charges and negative electric charges are generated in the semiconductor-type carbon nanotubes.

The positive electric charges or the negative electric charges generated in the semiconductor-type carbon nanotubes are extracted by the acceptor material, and only electric charges that are not extracted by the acceptor material remain in the semiconductor-type carbon nanotubes.

In step 5A and step 5B, the positive electric charges and the negative electric charges move in accordance with a potential gradient, that is, an internal electric field in the function layer 101 generated by potentials of the transparent electrode 102, the bias electrode 106, the first control electrode 104A, the second control electrode 104B, the first collection electrode 103A, and the second collection electrode 103B.

By appropriately setting the potentials of the respective electrodes, among the positive electric charges and the negative electric charges, potential energy for the first electric charges that are collected by the transparent electrode 102 can be made minimum in the vicinity of the transparent electrode 102, and potential energy for the second electric charges that are not collected by the transparent electrode 102 can be made minimum in the vicinity of the first collection electrode 103A and the second collection electrode 103B.

Among the positive electric charges and the negative electric charges, the first electric charges that are collected by the transparent electrode 102 can move between the function layer 101 and the transparent electrode 102 and are therefore collected by the transparent electrode 102 and are removed to an outside.

Behavior of the second electric charges that are not collected by the transparent electrode 102 among the positive electric charges and the negative electric charges differs between step 5A and step 5B.

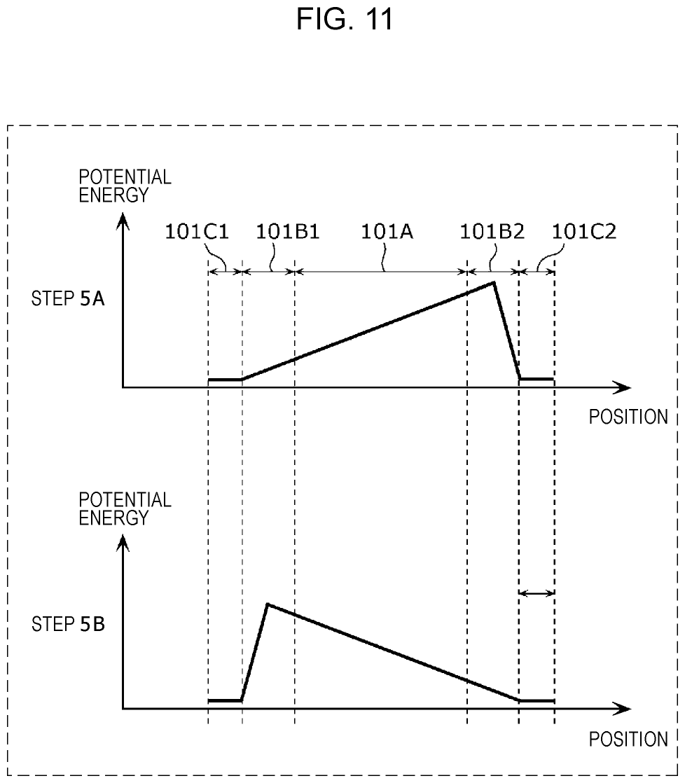

FIG. 11 schematically illustrates a potential distribution of the function layer 101 in step 5A and a potential distribution of the function layer 101 in step 5B. In FIG. 11, the horizontal axis represents a position in the function layer 101, and the vertical axis represents potential energy for the second electric charges of a polarity collected by the first collection electrode 103A and the second collection electrode 103B. That is, the second electric charges move to a side where the value of the vertical axis is lower. Hereinafter, potential energy is sometimes referred to simply as potential. The upper side in FIG. 11 illustrates a potential distribution of the function layer 101 in step 5A, and the lower side of FIG. 11 illustrates a potential distribution of the function layer 101 in step 5B.

As illustrated in FIG. 11, in step 5A, the following relationship is established: (the potential of the first transport modulation part 101B1)<(the potential of the electric charge generating part 101A)<(the potential of the second transport modulation part 101B2).

Accordingly, the second electric charges generated in the electric charge generating part 101A move to the first transport modulation part 101B1 and do not move to the second transport modulation part 101B2.

Furthermore, in step 5A, the following relationship is established: (the potential of the first electric charge exchange part 101C1)<(the potential of the first transport modulation part 101B1). Accordingly, the second electric charges that have moved to the first transport modulation part 101B1 further move to the first electric charge exchange part 101C1. The second electric charges that have moved to the first electric charge exchange part 101C1 move to the first electric charge accumulation region 105A via the first collection electrode 103A and are accumulated in the first electric charge accumulation region 105A. In this way, in step 5A, the second electric charges are collected by the first collection electrode 103A and are accumulated in the first electric charge accumulation region 105A.

Meanwhile, in step 5B, the following relationship is established: (the potential of the first transport modulation part 101B1) >(the potential of the electric charge generating part 101A) >(the potential of the second transport modulation part 101B2). Accordingly, the second electric charges generated in the electric charge generating part 101A move to the second transport modulation part 101B2 and do not move to the first transport modulation part 101B1.

Furthermore, in step 5B, the following relationship is established: (the potential of the second electric charge exchange part 101C2)<(the potential of the second transport modulation part 101B2). Accordingly, the second electric charges that have moved to the second transport modulation part 101B2 further move to the second electric charge exchange part 101C2. The second electric charges that have moved to the second electric charge exchange part 101C2 move to the second electric charge accumulation region 105B via the second collection electrode 103B and are accumulated in the second electric charge accumulation region 105B. In this way, in step 5B, the second electric charges are collected by the second collection electrode 103B and are accumulated in the second electric charge accumulation region 105B.

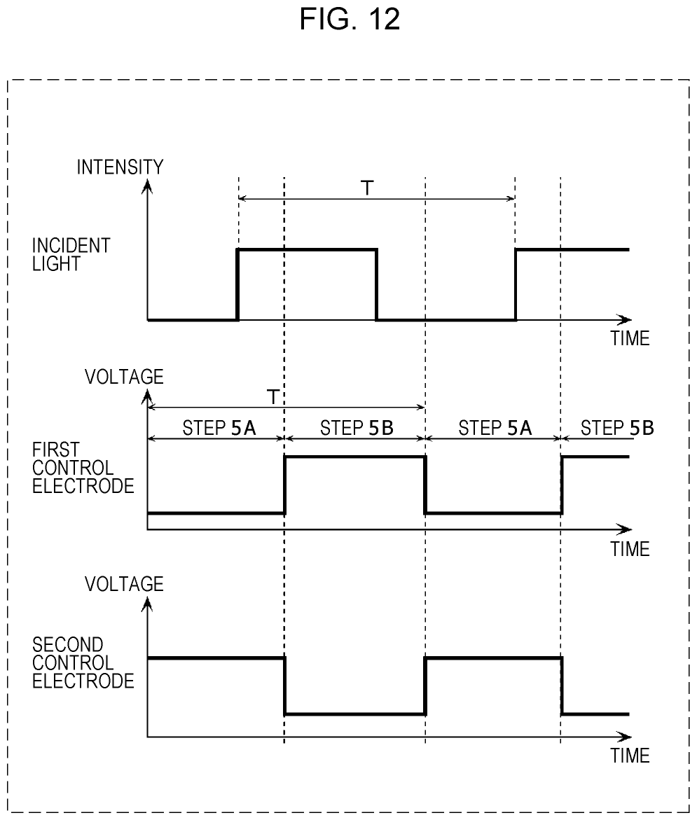

FIG. 12 illustrates an example of an intensity of the modulated light entering the image sensor 100 and a temporal change of a voltage applied to the first control electrode 104A and a voltage applied to the second control electrode 104B. FIG. 12 illustrates a case where modulated light modulated in a cycle T is emitted from a light source toward a subject and the reflected light enters the image sensor 100 by an imaging optical system. Furthermore, FIG. 12 illustrates a case where the modulated light is emitted at a constant intensity for a T/2 period and an irradiation intensity of the modulated light is set to 0 for a remaining T/2 period and this cycle is repeated. The topmost graph in FIG. 12 illustrates a temporal change of the intensity of the modulated light entering the image sensor 100. The second graph from the top in FIG. 12 illustrates a temporal change of the voltage applied to the first control electrode 104A. The lowermost graph in FIG. 12 illustrates a temporal change of the voltage applied to the second control electrode 104B.

A waveform of the incident light entering the image sensor 100 from the subject has a constant intensity for the same T/2 period as the emitted modulated light and has 0 intensity for the remaining T/2 period. However, a phase of the incident modulated light changes in accordance with a sum of a distance from the light source to the subject and a distance from the subject to the range image sensor. It is therefore possible to find a distance by measuring a phase of the incident modulated light in each of the pixels 10.

As described above, step 5A and step 5B are alternately repeated a predetermined number of times so that each step continues for a predetermined period. In the example illustrated in FIG. 12, step 5A and step 5B are alternately repeated so that each step continues for the same T/2 period as the incident modulated light. That is, a modulation frequency of the incident modulated light is the same as a frequency of the modulation control in step 5A and step 5B.

In step 6, an amount of electric charges accumulated in the first electric charge accumulation region Nfd1 and an amount of electric charges accumulated in the second electric charge accumulation region Nfd2 are measured.

A proportion of electric charges accumulated in the first electric charge accumulation region Nfd1 and a proportion of electric charges accumulated in the second electric charge accumulation region Nfd2 correspond to a ratio of an intensity of modulated light entering the image sensor during step 5A and an intensity of modulated light entering the image sensor during step 5B.

Start and end times of step 5A and step 5B are set by a user of the image sensor 100 and are therefore known. Accordingly, a phase of the incident modulated light can be decided on the basis of the amount of electric charges accumulated in the first electric charge accumulation region Nfd1, and therefore a distance to the subject can be decided. As described above, the function layer 101 includes a plurality of semiconductor-type carbon nanotubes in which mobility of electric charges is high, and therefore, movement of the second electric charges in the function layer 101 is faster than that in a conventional range image sensor. Accordingly, the second electric charges can move to the first collection electrode and the second collection electrode while following a frequency of modulation control higher than a conventional one. That is, movement of the second electric charges can be controlled at a high speed. As a result, a modulation frequency of modulated light used for distance measurement that contributes to an improvement of distance measurement accuracy can be increased. Therefore, the image sensor 100 can improve distance measurement accuracy.

Furthermore, by taking a difference between the amount of electric charges accumulated in the first electric charge accumulation region Nfd1 and the amount of electric charges accumulated in the second electric charge accumulation region Nfd2, a signal of incident light other than the modulated light and the like can be subtracted, and therefore distance measurement accuracy can be further increased.

Although operation of distance measurement imaging using the image sensor 100 has been described above, the second electric charges can be moved to the first collection electrode and the second collection electrode and movement of electric charges can be controlled at a high speed by similar operation even in modulation imaging other than distance measurement imaging.

### Embodiment 2

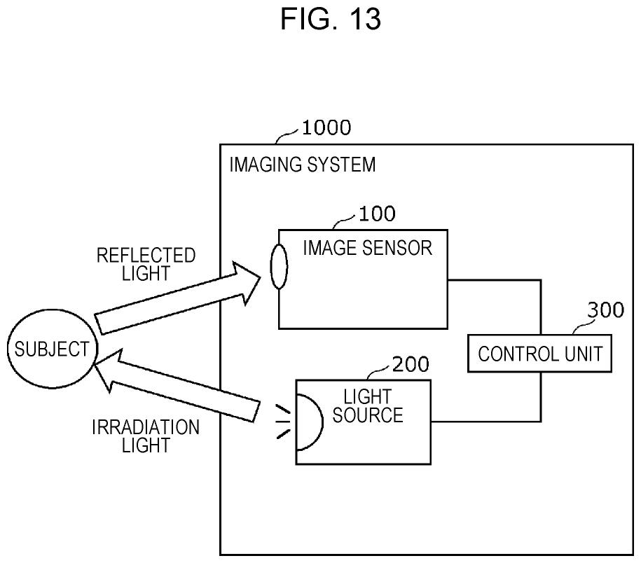

Next, Embodiment 2 is described. In Embodiment 2, an imaging system including the image sensor is described. FIG. 13 is a block diagram illustrating an example of a configuration of an imaging system 1000 according to the present embodiment.

As illustrated in FIG. 13, the imaging system 1000 according to the present embodiment includes the image sensor 100 according to Embodiment 1 and a light source 200 that emits light of a wavelength including a resonance wavelength of a plurality of semiconductor-type carbon nanotubes included in the image sensor 100. The imaging system 1000 further includes a control unit 300 that controls operation of the image sensor 100 and the light source 200.

In the imaging system 1000, light emitted from the light source 200 is reflected by a subject, and the reflected light is taken out as an electric signal by photoelectric conversion in the image sensor 100 and is thus imaged. Although the image sensor 100 and the light source 200 are described as separate members, the image sensor 100 and the light source 200 may be integral with each other and other light sources or image sensors may be combined.

The light source 200 can be any light source that emits light of a wavelength including a resonance wavelength of the plurality of semiconductor-type carbon nanotubes and is, for example, a laser including a laser diode. The light source 200 emits, for example, modulated light for distance measurement imaging. The light source 200 may modulate an intensity of a high-output laser as it is or may modulate a low-output laser and amplify the modulated light by an optical amplifier such as a rare-earth-doped fiber amplifier.

The control unit 300 controls operation such as imaging of the image sensor 100 and light emission of the light source 200. The control unit 300 includes, for example, a central processing unit (CPU), a random access memory (RAM), and a read only memory (ROM).

The imaging system 1000 according to the present embodiment includes the image sensor 100 according to Embodiment 1 and the light source 200 that emits light of a wavelength including a resonance wavelength of the plurality of semiconductor-type carbon nanotubes included in the image sensor 100. With this configuration, since the image sensor according to the above embodiment is provided and a wavelength to which the image sensor 100 has high sensitivity is emitted from the light source 200, and therefore the imaging system 1000 can control movement of electric charges at a high speed and increase sensitivity. As a result, for example, the imaging system 1000 can achieve high sensitivity and accuracy of distance measurement imaging.

### Other Embodiments

Although an image sensor and others according to one or plural aspects have been described above based on the embodiments, the present disclosure is not limited to these embodiments.

For example, although the transparent electrode 102 and the first collection electrode 103A, the second collection electrode 103B, the first control electrode 104A, and the second control electrode 104B are disposed so as to face each other with the function layer 101 interposed therebetween in the above embodiments, this is not restrictive. The transparent electrode 102 and the first collection electrode 103A, the second collection electrode 103B, the first control electrode 104A, and the second control electrode 104B may be disposed so as not to face each other as long as movement of the second electric charges generated in the electric charge generating part 101A to the first collection electrode 103A and the second collection electrode 103B can be controlled by the first control electrode 104A and the second control electrode 104B.

Furthermore, for example, although the image sensor 100 is used for distance measurement imaging in the above embodiments, this is not restrictive. The image sensor 100 may be used for modulation imaging other than distance measurement.

In addition, various modifications of the present embodiment which a person skilled in the art can think of and combinations of constituent elements in different embodiments are also encompassed within the scope of the present disclosure without departing of the spirit of the present disclosure.

The image sensor and others according to the present disclosure are, for example, applicable as a range image sensor. In particular, the image sensor and others according to the present disclosure are operable at a wavelength that is hard to be influenced by sunlight and are useful as an obstacle detection sensor or the like of an automobile, a drone, or the like.

What is claimed is:

1. An image sensor comprising:
a function layer including a photoelectric conversion region containing a plurality of semiconductor-type carbon nanotubes;
a transparent electrode that collects first electric charges that are positive electric charges or negative electric charges, the positive electric charges or the negative electric charges being generated in the photoelectric conversion region upon entry of light;
a first collection electrode that collects second electric charges having a polarity opposite to the first electric charges among the positive electric charges and the negative electric charges;
a second collection electrode that collects the second electric charges;
a first control electrode that controls movement of the second electric charges toward the first collection electrode;
a second control electrode that controls movement of the second electric charges toward the second collection electrode; and
an electric charge accumulator in which the second electric charges collected by the first collection electrode are accumulated.

2. The image sensor according to claim 1, wherein
the function layer further includes:
an electric charge exchange region in which the second electric charges generated in the photoelectric conversion region are exchanged with the first collection electrode; and
an electric charge transport region located between the photoelectric conversion region and the electric charge exchange region;
movement of the second electric charges from the photoelectric conversion region to the electric charge exchange region through the electric charge transport region is controlled by the first control electrode; and
the electric charge exchange region and the electric charge transport region each contain the plurality of semiconductor-type carbon nanotubes.

3. The image sensor according to claim 2, wherein
at least one of the plurality of semiconductor-type carbon nanotubes extends from the photoelectric conversion region to the electric charge exchange region.

4. The image sensor according to claim 2, wherein
a thickness of the function layer is smaller than a distance between the electric charge exchange region and the photoelectric conversion region.

5. The image sensor according to claim 2, wherein
an average length of the plurality of semiconductor-type carbon nanotubes is larger than a thickness of the function layer.

6. The image sensor according to claim 2, wherein
the transparent electrode is located above the function layer;
the first collection electrode and the second collection electrode are located below the function layer and face the transparent electrode;
the first control electrode and the second control electrode are located below the function layer, the first control electrode and the second control electrode facing the transparent electrode, the first control electrode and the second control electrode being located between the first collection electrode and the second collection electrode;
the electric charge exchange region is located between the first collection electrode and the transparent electrode; and
the electric charge transport region is located between the first control electrode and the transparent electrode, the electric charge transport region being adjacent to the photoelectric conversion region and the electric charge exchange region.

7. The image sensor according to claim 6, further comprising a bias electrode that is located below the function layer and that faces the transparent electrode with the photoelectric conversion region interposed between the transparent electrode and the bias electrode.

8. The image sensor according to claim 6, further comprising:
a lens that is located above the transparent electrode and that focuses light coming from an upper side onto the photoelectric conversion region; and
a light-shielding body located between the transparent electrode and the lens,
wherein the light-shielding body is located outside the photoelectric conversion region and overlaps the electric charge exchange region and the electric charge transport region in top view.

9. The image sensor according to claim 1, wherein
the photoelectric conversion region further contains an acceptor material that receives the first electric charges generated in the photoelectric conversion region.

10. An imaging system comprising:
the image sensor according to claim 1; and
a light source that emits light having a wavelength including a resonance wavelength of the plurality of semiconductor-type carbon nanotubes.
